(19) United States
(12) Patent Application Publication
(10) Pub. No.: US 2026/0107834 A1
(43) Pub. Date: Apr. 16, 2026

(54) SEMICONDUCTOR MODULE INCLUDING A BACKSIDE CAPACITOR, PACKAGE STRUCTURE INCLUDING THE SEMICONDUCTOR MODULE AND METHODS OF FORMING THE SAME

(71) Applicant: Taiwan Semiconductor Manufacturing Company Limited, Hsinchu (TW)

(72) Inventors: Chieh-Lung LAI, Taichung City (TW); Meng-Liang LIN, Hsinchu (TW); Hsien-Wei CHEN, Hsinchu City (TW); Kathy YAN, Hsinchu (TW)

(21) Appl. No.: 18/915,055

(22) Filed: Oct. 14, 2024

(51) Int. Cl. H01L 25/16; H01L 21/48; H01L 21/56; H01L 23/00; H01L 23/31; H01L 23/498; H01L 23/64

(52) U.S. Cl. CPC H10W 90/00; H10D 1/692; H10W 44/601; H10W 70/05; H10W 70/093; H10W 70/095; H10W 70/685; H10W 74/016; H10W 74/117; H10W 74/121; H10W 90/701; H10W 72/07236; H10W 90/724

(57) ABSTRACT

A semiconductor module includes an interposer, a plurality of semiconductor dies on the interposer, wherein each semiconductor die of the plurality of semiconductor dies has a frontside surface facing the interposer and a backside surface opposite to the interposer, and a backside capacitor on the backside surface of at least one of the plurality of semiconductor dies and electrically coupled to the interposer.

### BACKGROUND

The semiconductor industry has grown due to continuous improvements in integration density of various electronic components (e.g., transistors, diodes, resistors, capacitors, etc.). These various electronic components may include integrated passive devices (IPD) such as capacitors.

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these three-dimensional devices are prepared by placing chips over chips. These three-dimensional devices provide improved integration density and other advantages because of the decreased length of interconnects between the stacked chips. However, there are many challenges related to three-dimensional devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view (front view) of a semiconductor module according to one or more embodiments.

FIG. 1B is a detailed vertical cross-sectional view (front view) of the semiconductor module according to one or more embodiments.

FIG. 1C is a detailed vertical cross-sectional view (front view) of a backside capacitor in the semiconductor module according to one or more embodiments.

FIG. 1D is a vertical cross-sectional view (side view) of the semiconductor module according to one or more embodiments.

FIG. 1E is a plan view (e.g., top-down view) of the package structure (omitting the backside capacitor) according to one or more embodiments.

FIG. 1F is a plan view (e.g., top-down view) of the package structure (including a location of parallel metal films in the backside capacitor) according to one or more embodiments.

FIG. 2A is a vertical cross-sectional view of an intermediate structure including an interposer (e.g., organic interposer) formed on a carrier substrate (e.g., carrier wafer) according to an embodiment of the present invention.

FIG. 2B is a vertical cross-sectional view of an intermediate structure including the first semiconductor die and the second semiconductor die according to one or more embodiments.

FIG. 2C is a vertical cross-sectional view of an intermediate structure including the semiconductor module underfill layer according to one or more embodiments.

FIG. 2D illustrates a vertical cross-sectional view of an intermediate structure including the upper molding layer according to one or more embodiments.

FIG. 2E illustrates a vertical cross-sectional view of an intermediate structure including the first TMV and second TMV, according to one or more embodiments.

FIG. 2F illustrates a vertical cross-sectional view of an intermediate structure after a planarization process, according to one or more embodiments.

FIG. 2G illustrates a vertical cross-sectional view of an intermediate structure including the backside capacitor, according to one or more embodiments.

FIG. 2H illustrates a vertical cross-sectional view of an intermediate structure including the plurality of C4 bumps, according to one or more embodiments.

FIG. 3 is a flow chart illustrating a method of making a semiconductor module according to one or more embodiments

FIG. 4A is a vertical cross-sectional view (front view) of the package structure according to one or more embodiments.

FIG. 4B is a vertical cross-sectional view (side view) of the package structure according to one or more embodiments.

FIG. 5A is a vertical cross-sectional view of an intermediate structure including the package substrate having package substrate upper bonding pads and package substrate lower bonding pads, according to one or more embodiments.

FIG. 5B illustrates a vertical cross-sectional view of an intermediate structure in which the semiconductor module may be mounted on the package substrate, according to one or more embodiments.

FIG. 5C illustrates a vertical cross-sectional view of an intermediate structure in which the package underfill layer may be formed on the package substrate according to one or more embodiments.

FIG. 5D illustrates a vertical cross-sectional view of an intermediate structure in which the TIM layer may be attached to (e.g., formed on) the backside capacitor according to one or more embodiments.

FIG. 5E illustrates a vertical cross-sectional view of an intermediate structure in which the adhesive layer may be applied to the package substrate according to one or more embodiments.

FIG. 5F illustrates a vertical cross-sectional view of an intermediate structure in which the package lid may be attached to (e.g., mounted on) the package substrate according to one or more embodiments.

FIG. 5G illustrates a vertical cross-sectional view of an intermediate structure in which the BGA including a plurality of solder balls may be formed on the package substrate according to one or more embodiments.

FIG. 6 is a flow chart illustrating a method of forming the package structure according to one or more embodiments.

FIG. 7A is a vertical cross-sectional view of the semiconductor module having the first alternative configuration according to one or more embodiments.

FIG. 7B is a top-down view of the semiconductor module having the first alternative configuration according to one or more embodiments.

FIG. 8A is a vertical cross-sectional view of the semiconductor module having the second alternative configuration according to one or more embodiments.

FIG. 8B is a top-down view of the semiconductor module having the second alternative configuration according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

A capacitor may be included in a semiconductor module (e.g., a chip-on-wafer (CoW) structure). The semiconductor module may be for applications such as high-performance computing (HPC), radio frequency (RF) and microwave circuits, automotive electronics and mobile devices. The capacitor may be included as an integrated passive device (IPD) attached to the semiconductor module. The IPD may be located under the semiconductor module such as on an underside of the interposer in the semiconductor module. The capacitor may also be included, for example, as an embedded deep trench capacitor (eDTC). The capacitor may be integrated into a semiconductor module to improve performance, size, and/or efficiency.

The capacitor may be used, for example, as a decoupling capacitor to filter out noise and stabilize the power supply voltage to the semiconductor module. A decoupling capacitor may provide a local charge reservoir that helps to smooth out voltage fluctuations, ensuring a stable power supply for the circuits (e.g., integrated circuits) in the semiconductor module. The capacitor may also be used for noise reduction. By being physically close to the active circuits in the semiconductor module, these capacitors may reduce the effects of electromagnetic interference (EMI) and crosstalk, improving signal integrity and overall device performance.

The capacitor may also be used to maintain power integrity in the semiconductor module. In particular, the capacitor may help ensure that the voltage levels within the semiconductor module remain stable, especially during rapid changes in power consumption by different parts of the circuits in the semiconductor module. The capacitor may also help smooth out rapid current changes, preventing voltage drops (known as droop) that could lead to malfunction or reduced performance of the circuits.

The capacitor may also be used to maintain signal integrity in the semiconductor module. In particular, the semiconductor module may be used to filter out high-frequency noise from signals, ensuring that only the desired signal frequencies pass through. Further, in radio frequency (RF) and high-speed digital circuits, the capacitor may be used to match impedance, minimizing signal reflection and loss, thereby improving signal transmission quality.

Further, by including the capacitor in the semiconductor module, the need for discrete components (e.g., on a printed circuit board (PCB)) may be avoided leading to a smaller overall device footprint. By locating the capacitor closer to the active circuits, parasitic inductance and resistance may also be minimized, leading to better performance, especially in high-frequency applications. The capacitor may also help to manage heat distribution in the semiconductor module by helping to dissipate heat away from critical areas, improving the reliability and longevity of the semiconductor module.

At least one embodiment of the present disclosure may include a CoW (or chip-on-wafer-on-substrate) backside capacitor (e.g., backside film structure). At least one embodiment may implement the backside capacitor with both backside metal (BSM) and passivation film on a backside of the CoW. The advantages of at least one embodiment may include enabling more capacitor (e.g., greater capacitance) close to the chip. In particular, at least one or more embodiments may enable a film capacitor at a CoW backside and in parallel provide both low CoW warpage (e.g., a warpage tuning film) and low thermal resistance.

At least one embodiment may include a silicon-based chip (system on chip (SoC), high bandwidth memory (HBM), etc.), an interposer, a molding material layer (upper molding layer), one or more interconnects (e.g., C4 bumps), a package substrate, a backside film capacitor and one or more through molding vias (TMVs).

The TMVs may connect the backside capacitor (backside film capacitor) to one or more metal layers (e.g., redistribution layer (RDL) structure) in the semiconductor module (e.g., in the interposer of the semiconductor module. The TMVs may be formed of a metal or other suitable electrically conductive material. The backside capacitor may be formed on the backside of the semiconductor module and may be formed of a plurality of metal films and one or more passivation films.

In at least one embodiment, an area of the backside capacitor may be in a range from 10% to 100% of the backside area of the semiconductor module. A thickness of the backside capacitor may be in a range from 0.1 μm to 10,000 μm.

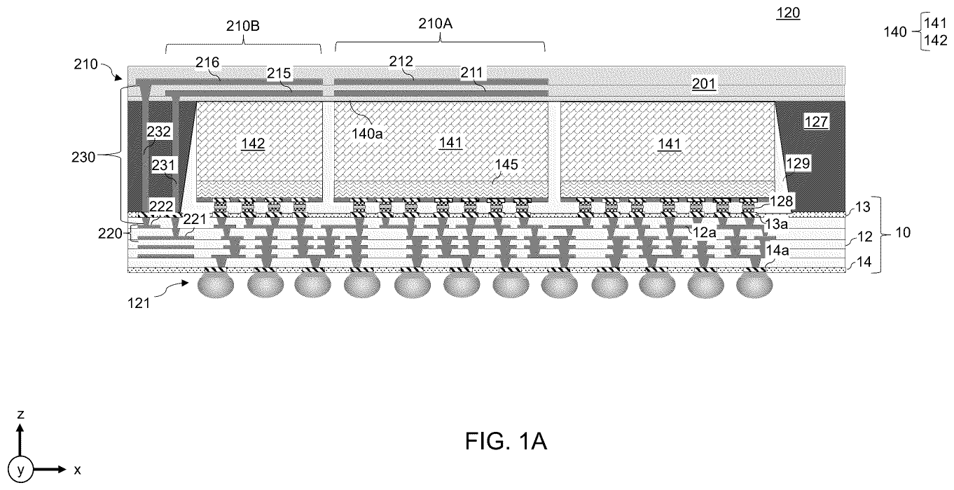

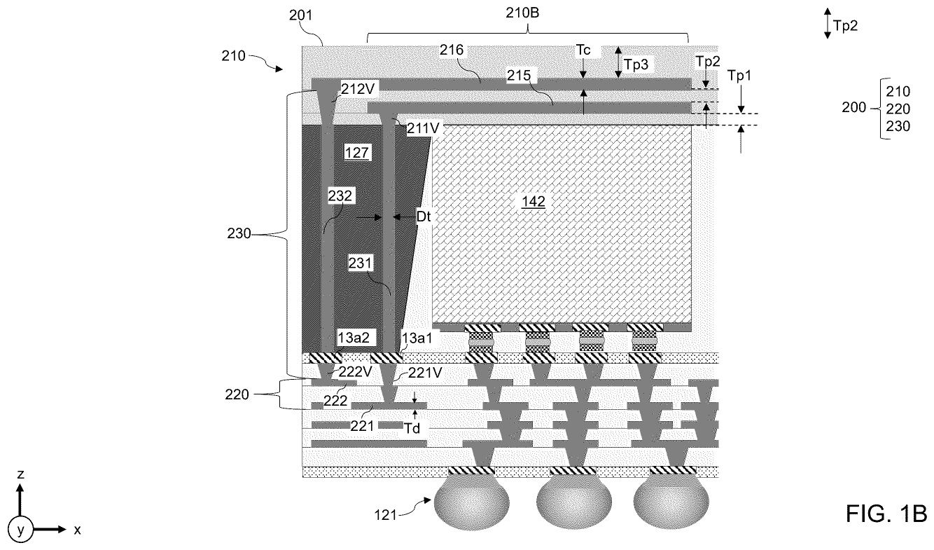

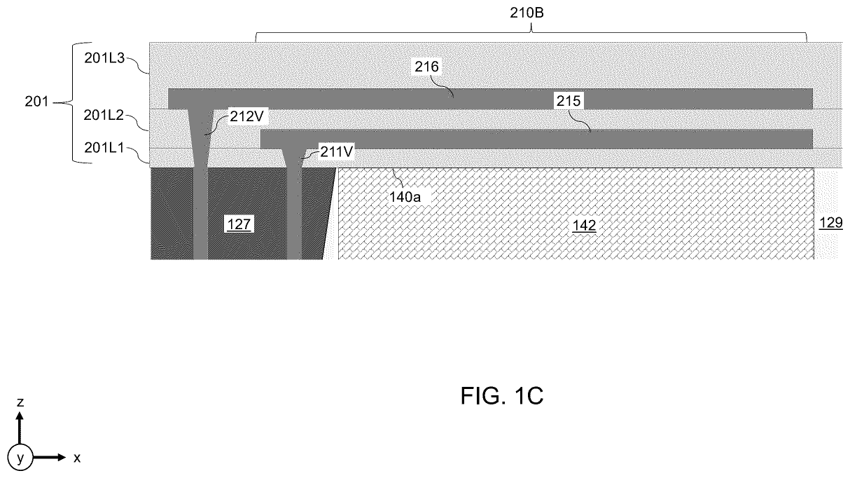

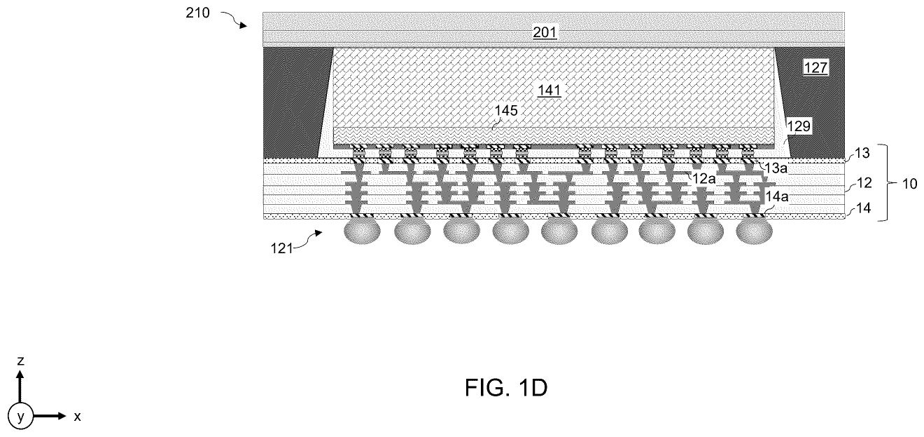

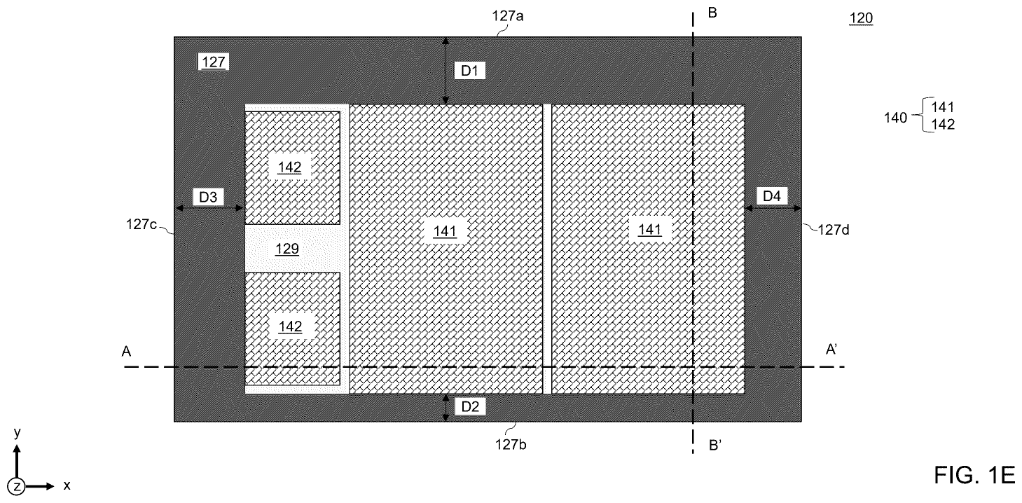

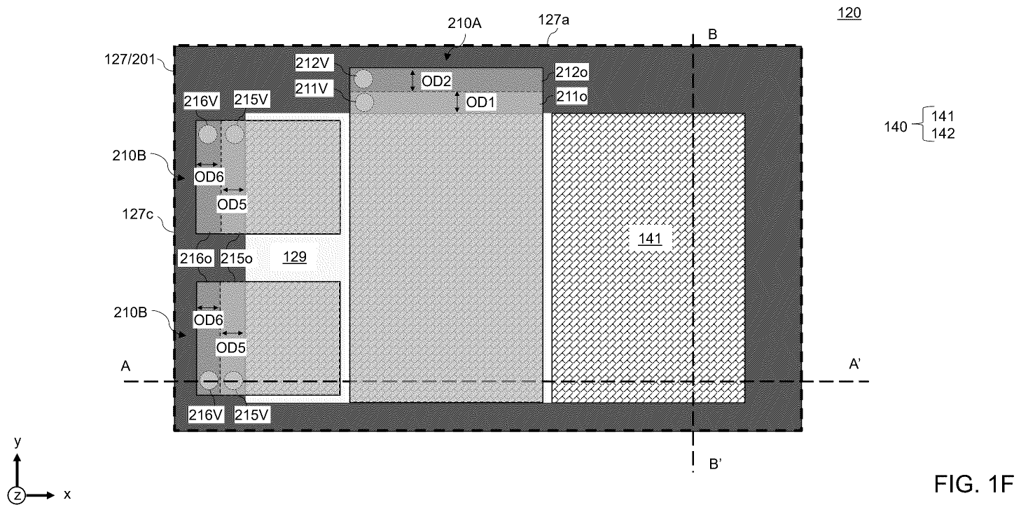

FIG. 1A is a vertical cross-sectional view (front view) of a semiconductor module 120 according to one or more embodiments. FIG. 1B is a detailed vertical cross-sectional view (front view) of the semiconductor module 120 according to one or more embodiments. FIG. 1C is a detailed vertical cross-sectional view (front view) of a backside capacitor 210 in the semiconductor module 120 according to one or more embodiments. FIG. 1D is a vertical cross-sectional view (side view) of the semiconductor module 120 according to one or more embodiments. FIG. 1E is a plan view (e.g., top-down view) of the package structure 100 (omitting the backside capacitor 210) according to one or more embodiments. FIG. 1F is a plan view (e.g., top-down view) of the package structure 100 (including a location of parallel metal films in the backside capacitor 210) according to one or more embodiments. The vertical cross-sectional view (front view) in FIG. 1A is along the line A-A′ in FIGS. 1E and 1F. The vertical cross-sectional view (side view) in FIG. 1D is along the line B-B′ in FIGS. 1E and 1F.

As illustrated in FIG. 1A, the semiconductor module 120 may include an interposer 10, one or more semiconductor dies 140 on the interposer 10 and a backside capacitor 210 over and adjacent to the one or more semiconductor dies 140. The backside capacitor 210 may be electrically coupled to the interposer 10. The semiconductor module 120 is not limited to any particular configuration. The semiconductor module 120 may include, for example, a chip-on-wafer (CoW) design, an integrated fan-out design, and so on. In at least one embodiment, the interposer 10 may be replaced with one or more substrates in the semiconductor module 120.

The interposer 10 is not necessarily limited to any particular materials or configuration. The interposer 10 may include, for example, organic material (e.g., dielectric polymer), inorganic material (e.g., silicon), glass substrate, etc. In at least one embodiment, the interposer 10 may include a plurality of polymer layers 12 (i.e. dielectric layers) and a plurality of redistribution layers 12a stacked alternately. The number of the polymer layers 12 and/or the number of redistribution layers 12a in the interposer 10 are not limited by the disclosure.

In at least one embodiment, the polymer layers 12 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 12a may include conductive materials. The conductive materials may include metal such as copper, aluminum, nickel, titanium, a combination thereof or other suitable metals.

The redistribution layers 12a may include metallic connection structures, i.e., metallic structures that provide electrical connection between nodes in the structure. The redistribution layers 12a may include a metallic seed layer (not shown) and a metallic fill material (not shown) on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm. The metallic fill material for the redistribution layers 12a may include copper, nickel, or copper and nickel. Other suitable metallic fill materials are within the contemplated scope of disclosure. The thickness of the metallic fill material that is deposited for each redistribution layer 12a may be in a range from 2 microns to 40 microns, such as from 4 microns to 10 microns, although lesser or greater thicknesses may also be used.

In at least one embodiment, the redistribution layers 12a may include a plurality of metal traces (lines) and a plurality of metal vias connecting the plurality of metal traces to each other. The metal traces may be respectively located on the polymer layers 12 and may extend in the x-direction (first horizontal direction) and y-direction (second horizontal direction) on an upper surface of the polymer layers 12. The metal vias may extend in the z-direction between the polymer layers 12.

An upper passivation layer 13 may be formed on the chip-side surface of the interposer 10. The upper passivation layer 13 may include silicon oxide, silicon nitride, low-k dielectric materials such as carbon-doped oxides, extremely low-k dielectric materials such as porous carbon doped silicon dioxide, a combination thereof or other suitable material.

One or more upper bonding pads 13a may be formed in the upper passivation layer 13 on the chip-side surface of interposer 10. The upper passivation layer 13 may at least partially cover the upper bonding pads 13a. That is, the upper bonding pads 13a may be at least partially exposed on the chip-side surface of the interposer 10. The upper bonding pads 13a may be electrically coupled to the redistribution layers 12a. The upper bonding pads 13a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A lower passivation layer 14 may be formed on the board-side surface of the interposer 10. The lower passivation layer 14 may also include silicon oxide, silicon nitride, low-k dielectric materials such as carbon-doped oxides, extremely low-k dielectric materials such as porous carbon doped silicon dioxide, a combination thereof or other suitable material. The lower bonding pads 14a may be electrically coupled to the redistribution layers 12a. The lower bonding pads 14a may be located in the lower passivation layer 14. The lower passivation layer 14 may at least partially cover the lower bonding pads 14a. That is, the lower bonding pads 14a may be at least partially exposed on the board-side surface of the interposer 10. The lower bonding pads 14a may also include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The semiconductor module 120 may further include C4 bumps 121 (e.g., collapsible SnAg solder bumps) on the board-side surface of the interposer 10. The semiconductor module 120 may be bonded to and electrically coupled to a package substrate (not shown) by the C4 bumps 121. The C4 bumps 121 may be formed on the lower bonding pads 14a on the board-side surface of the interposer 10, respectively. The C4 bumps 121 may be bonded to the package substrate using solder reflow, compression bonding, thermocompression bonding, etc. In at least one embodiment, the C4 bumps 121 may include underbump metallurgy (UBM) layers (not shown) on the lower bonding pads 14a. In at least on embodiment, the C4 bumps 121 may include a contact pad (e.g., copper/nickel contact pad) on the UBM layers and a layer of SnAg solder material on the contact pad.

The semiconductor dies (collectively referred to as semiconductor dies 140) may be attached to an upper surface of the interposer 10. The plurality of semiconductor dies 140 may include a first semiconductor die 141 and second semiconductor die 142. Although the semiconductor module 120 is illustrated as including a particular number of the semiconductor dies 140 of particular sizes having a particular arrangement, the number of semiconductor dies 140, the sizes of the semiconductor dies 140 and the arrangement of the semiconductor dies 140 is not limited to any particular number, size and arrangement. In particular, the semiconductor module 120 may include any number, size and arrangement of the semiconductor dies 140.

The semiconductor dies 140 may include an active region 145 including active devices such as transistors. The semiconductor dies 140 may also include a bulk silicon region on the active region 145. Generally, a thickness in the z-direction of each of the semiconductor dies 140 may be substantially the same. Thus, the upper surface (e.g., backside surface) of each of the first semiconductor die 141 and second semiconductor die 142 may be substantially coplanar (e.g., formed in the same x-y plane), and referred to collectively as the semiconductor die upper surface 140a. Each of the first semiconductor die 141 and second semiconductor die 142 may include a lower surface (e.g., frontside surface) opposite the upper surface and facing the interposer 10.

The semiconductor dies 140 may be attached to (e.g., bonded to) the upper bonding pads 13a on the chip-side surface of the interposer 10 by microbumps 128. The microbumps 128 may electrically couple the active region 145 of the semiconductor dies 140 to the upper bonding pads 13a of the interposer. The microbumps 128 may each include a copper post and a solder bump on the copper post. Other suitable interconnect structures may be used in place of the microbumps 128.

A semiconductor module underfill layer 129 may be formed (e.g., individually or collectively) under and around each of the semiconductor dies 140. In at least one embodiment, a height of an upper surface of the semiconductor module underfill layer 129 may be substantially coplanar with the upper surface 140a of the semiconductor dies 140. In at least one embodiment, the height of the upper surface of the semiconductor module underfill layer 129 may be less than the height of the upper surface 140a of the semiconductor dies 140.

The semiconductor module underfill layer 129 may also be formed around the microbumps 128. The semiconductor module underfill layer 129 may be formed on a bonded to the upper surface of the interposer 10 (e.g., an upper surface of the upper passivation layer 13). The semiconductor module underfill layer 129 may thereby fix each of the semiconductor dies 140 to the interposer 10. The semiconductor module underfill layer 129 may be formed of an epoxy-based polymeric material. Other suitable materials may be used for the semiconductor module underfill layer 129.

Each of the semiconductor dies 140 may include, for example, a singular semiconductor die structure, a system on chip (SoC) die, or a system on integrated chips (SoIC) die, and may be implemented by a three-dimensional integrated packaging technology (e.g., fan-out technology). In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, a NAND die, static random access memory (SRAM), etc. ), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an IPD die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the first semiconductor die 141 may include a primary die (e.g., SOC die), and the second semiconductor die 142 may include an ancillary die (e.g., HBM die).

The semiconductor module 120 may also include an upper molding layer 127 formed around the semiconductor dies 140. The upper molding layer 127 may have an outer sidewall that is substantially aligned with the outer sidewall of the interposer 10. The upper molding layer 127 may also have an upper surface that is substantially uniform (e.g., flat) and substantially coplanar with the upper surface 140a of the semiconductor dies 140.

The upper molding layer 127 may also be formed on and around the semiconductor module underfill layer 129. Although it is not illustrated in FIG. 1A, in a case where a height of an upper surface of the semiconductor module underfill layer 129 is less than a height of upper surface 140a of the semiconductor dies 140, the upper molding layer 127 may be formed on and bonded to inner sidewalls and/or outer sidewalls of each of the semiconductor dies 140. In particular, the upper molding layer 127 may be formed in a die-to-die gap between the semiconductor dies 140 and bonded to the inner sidewalls of the semiconductor dies 140. The upper molding layer 127 may also be formed on the semiconductor module underfill layer 129 in the die-to-die gap. The upper molding layer 127 may also be bonded to the chip-side surface of the interposer 10 (e.g., the upper surface of the upper passivation layer 13) and the semiconductor module underfill layer 129.

In at least one embodiment, the upper molding layer 127 may be formed of a curable material that may cure to form a hard, solid structure. The upper molding layer 127 may include, for example, epoxy molding compound (EMC). In at least one embodiment, the upper molding layer 127 may include a material that is substantially similar to the package underfill layer 119 and semiconductor module underfill layer 129. In at least one embodiment, the upper molding layer 127 may include a polymeric material and in particular, an epoxy-based polymeric material. Other suitable molding materials may be used.

In at least one embodiment, the upper molding layer 127 may have a coefficient of thermal expansion (CTE) that is substantially similar to a CTE of the interposer 10. In at least one embodiment, the upper molding layer 127 may include an added material (e.g., filler material added to a polymeric material) for improving a property of the upper molding layer 127 (e.g., thermal conductivity, CTE, etc.). The added material may include, for example, a non-electrically conductive powder such as an oxide powder, etc. Other filler materials in the upper molding layer 127 are within the contemplated scope of the disclosure.

As illustrated in FIG. 1A, the backside capacitor 210 may include a passivation film 201 and one or more capacitors in the passivation film 201. The passivation film 201 may contact an entire upper surface of the upper molding layer 127 and the upper surface 140a of the semiconductor dies 140. The passivation film 201 may also contact an upper surface of the semiconductor module underfill layer 129 between the semiconductor dies 140. In at least one embodiment, a sidewall of the passivation film 201 may be substantially aligned with a sidewall of the upper molding layer 127.

The capacitors 210 may include, for example, a first capacitor 210A over the first semiconductor die 141 and a second capacitor 210B over the second semiconductor die 142 (e.g., the outermost semiconductor die). The first capacitor 210A may include a plurality of parallel metal films including a first metal film 211 and second metal film 212 in the passivation film 201. In at least one embodiment, the second metal film 212 may extend in at least one direction (e.g., the x-direction) beyond the first metal film 211 to allow the second metal film 212 to be connected from below to the interposer 10. The second capacitor 210B may include a plurality of parallel metal films including a first metal film 215 and second metal film 216 in the passivation film 201. Although it is not shown in FIG. 1A, the second metal film 216 may extend in at least one direction (e.g., the y-direction) beyond the first metal film 215 to allow the second metal film 216 to be connected from below to the interposer 10.

Although only one backside capacitor 210 is shown in FIG. 1A, additional backside capacitors 210 may be stacked on the backside capacitor 210 shown in the semiconductor module 120. Further, while only two capacitors are shown in the backside capacitor 210 in FIG. 1A, the backside capacitor 210 may include any number of capacitors. Further, a size and location of the first capacitor 210A and second capacitor 210B is not necessarily limited to the size and location in FIG. 1A. That is, the first capacitor 210A and second capacitor 210B may have any size and any location in the backside capacitor 210.

The semiconductor module 120 may also include a distribution structure 220 in the interposer 10. In at least one embodiment, the distribution structure 220 may include a plurality of metal traces in the redistribution layers 12a (e.g., a redistribution layer (RDL) structure). The distribution structure 220 may include, for example, a first distribution line 221 electrically coupled to the first metal film 215 of the second capacitor 210B in the backside capacitor 210. The distribution structure 220 may also include a second distribution line 222 electrically coupled to the second metal film 216 of the second capacitor 210B in the backside capacitor 210. Although it is not shown in FIG. 1A, the distribution structure 220 may include an additional distribution line (e.g., redistribution layers 12a) electrically coupled to the first metal film 211 of the first capacitor 210A, and an additional distribution line electrically coupled to the second metal film 212 of the first capacitor 210A.

The semiconductor module 120 may also include a connecting structure 230 that electrically couples the backside capacitor 210 to the distribution structure 220 in the interposer 10. The connecting structure 230 may include a plurality of through molding vias (TMVs) including a first TMV 231 electrically coupling the first metal film 215 in the second capacitor 210B to the first distribution line 221 of the distribution structure 220. The plurality of TMVs in the connecting structure 230 may also include a second TMV 232 electrically coupling the second metal film 216 in the second capacitor 210B to the second distribution line 222 of the distribution structure 220. Although it is not shown in FIG. 1A, the connecting structure 230 may include additional TMVs for connecting the first metal layer 211 and second metal layer 212 of the first capacitor 210A to the distribution structure 220. The connecting structure 230 may also include additional elements in the interposer 10 and passivation film 201, as described in more detail below.

The semiconductor module 120 having the backside capacitor 210 may have several advantages over related semiconductor modules. In particular, the backside capacitor 210 may enable more capacitor (e.g., greater capacitance) close to the semiconductor dies 140 in the semiconductor module 120. In at least one embodiment, the backside capacitor 210 may provide a capacitance density greater than 10 nf/mm². In at least one embodiment, depending on a thickness of semiconductor dies 140, the backside capacitor 210 may be closer to the active region 145 of the semiconductor dies 140 by a distance of 50 μm to 775 μm, compared to a conventional semiconductor module 120. This may help to reduce electrical resistance between the capacitor and the active regions 145. The semiconductor module 120 including the backside capacitor 210 may be especially useful in high power consumption ICs including, for example, logic/power IC, memory, chiplet, I/O chips, 3D IC, etc.

In addition, the backside capacitor 210 may help to reduce warpage of the semiconductor module 120. In at least one embodiment, the backside capacitor 210 may serve as a CoW warpage tuning film. Warpage reduction may be due to both the passivation film 201 and the pairs of parallel metal films in the backside capacitor 210. Further, the backside capacitor 210 may help to reduce thermal resistance so that heat is dissipated more easily from the semiconductor module 120.

Referring again to FIG. 1B, the backside capacitor 210 may be included in the semiconductor module 120 as part of a charge storing structure 200. The charge storing structure may also include the distribution structure 220 and the connecting structure 230. The various parts of the charge storing structure 200 may be composed of conductive materials such as metal materials (e.g., copper).

In the backside capacitor 210, each of the first metal film 215 and second metal film 216 of the second capacitor 210B (and each of the first metal film 211 and second metal film 211 of the first capacitor 210A) may be composed of a conductive material. In at least one embodiment, the each of the first metal film 215 and second metal film 216 of the second capacitor 210B (and each of the first metal film 211 and second metal film 211 of the first capacitor 210A) may be composed one or more metal layers including a metal, metal alloys, and/or other metal-containing compounds (e.g., Cu, Al, Mo, Co, Ru, W, TiN, TaN, WN, etc.). In at least one embodiment, each of the first metal film 215 and second metal film 216 of the second capacitor 210B (and each of the first metal film 211 and second metal film 211 of the first capacitor 210A) may have a thickness Tc in a range from 0.1 μm to 100 μm. The metal films of the first capacitor 210A may be substantially parallel and the metal films of the second capacitor 210B may be substantially parallel. The metals films of the first capacitor 210A and second capacitor 210B may have the same or different thicknesses and may be composed of the same or different materials.

In the distribution structure 220, each of the first distribution line 221 and the second distribution line 222 may be composed of the same material as the other redistribution layers 12a in the interposer 10. In at least one embodiment, each of the first distribution line 221 and the second distribution line 222 may be composed of one or more metal layers including a metal, metal alloys, and/or other metal-containing compounds (e.g., Cu, Al, Mo, Co, Ru, W, TiN, TaN, WN, etc.). In at least one embodiment, the each of the first distribution line 221 and the second distribution line 222 may have a thickness Td in a range from 0.01 μm to 100 μm. The first distribution line 221 and the second distribution line 222 may have the same or different thicknesses and may be composed of the same or different materials.

In the connecting structure 230, each of the first TMV 231 and the second TMV 232 may have a height substantially the same as a thickness of the upper molding layer 127. Further, each of the first TMV 231 and second TMV 232 may be composed of one or more metal layers including a metal, metal alloys, and/or other metal-containing compounds (e.g., Cu, Al, Mo, Co, Ru, W, TiN, TaN, WN, etc.). Each of the first TMV 231 and second TMV 232 may have a diameter Dt (e.g., width) in a range of 10 μm to 1000 μm.

In addition to the first TMV 231 and the second TMV 232, the connecting structure 230 may include a first upper via 211V in the passivation film 201 of the backside capacitor 210. The first upper via 211V (upper connecting portion) may connect the first metal film 215 of the second capacitor 210B to the first TMV 231 in the upper molding layer 127. The connecting structure 230 may include a second upper via 212V (upper connecting portion) in the passivation film 201. The second upper via 212V may connect the second metal film 216 of the second capacitor 210B to the second TMV 232 in the upper molding layer 127. Each of the first upper via 211V and the second upper via 212V may be composed of one or more metal layers including a metal, metal alloys, and/or other metal-containing compounds (e.g., Cu, Al, Mo, Co, Ru, W, TiN, TaN, WN, etc.).

The connecting structure 230 may also include a first upper bonding pad 13a1 and one or more first lower vias 221V in the interposer 10. The first upper bonding pad 13a1 and first lower vias 221V (which may be collectively referred to as a lower connecting portion) may connect the first distribution line 221 of the distribution structure 220 to the first TMV 231 in the upper molding layer 127. The connecting structure 230 may also include a second upper bonding pad 13a2 and one or more second lower vias 222V (which may also be collectively referred to as a lower connecting portion) in the interposer 10. The second upper bonding pad 13a2 and second lower vias 222V may connect the second distribution line 222 of the distribution structure 220 to the second TMV 232 in the upper molding layer 127.

The first upper bonding pad 13a1 and second upper bonding pad 13a2 may have a size and shape substantially the same as the other upper bonding pads 13a in the interposer 10. The first upper bonding pad 13a1 and second upper bonding pad 13a2 may also be composed of substantially the same materials as the other upper bonding pads 13a in the interposer 10. The first lower vias 221V and second lower vias 222V may have a size and shape substantially the same as the other metal vias in the redistribution layers 12a in the interposer 10. The first lower vias 221V and second lower vias 222V may also be composed of substantially the same materials as the other metal vias in the redistribution layers 12a of the interposer 10.

The passivation film 201 may include one or more layers of passivation materials. In at least one embodiment the passivation film 201 may include one or more layers of dielectric materials. In at least one embodiment, the materials in the passivation film 201 above and/or below the parallel metal films of the first capacitor 210A (first metal film 211 and second metal film 212) and above and/or below the parallel metal films of the second capacitor 210B (first metal film 215 and second metal film 216) may be different than the materials in the passivation film 201 between the parallel metal films of the first capacitor 210A and the parallel metal films of the second capacitor 210B. In at least one embodiment, the passivation film 201 may include SiNx, SiOx, polybenzoxazole (PBO), polyimide (PI), Ajinomoto Build-up Film (ABF) and bismaleimide triazine (BT). Other suitable materials may be used in the passivation film 201.

In at least one embodiment, the passivation film 201 may have a first thickness Tp1 between the semiconductor dies 140 and the first metal plate 215 of the second capacitor (and between the semiconductor dies 140 and the first metal plate 211 of the first capacitor 210A). The passivation film 201 may also include a second thickness Tp2 between the parallel metal plates of the second capacitor 210B (and between the parallel metal plates of the first capacitor 210A). The passivation film 201 may also include a third thickness Tp3 above the parallel metal plates of the second capacitor 210B (and above the parallel metal plates of the first capacitor 210A).

In at least one embodiment, the second thickness Tp2 may be less than the third thickness Tp3. In at least one embodiment, the third thickness Tp3 may be at least twice the second thickness Tp2. In at least one embodiment, the second thickness Tp2 may be substantially the same as the first thickness Tp1. In at least one embodiment, the first thickness Tp1 may be less than the second thickness Tp2. In at least one embodiment, each of the first thickness Tp1 and the second thickness Tp2 may be in a range from 0.01 μm to 100 μm. In at least one embodiment, the third thickness Tp3 may be in a range from 0.1 μm to 100 μm. In at least one embodiment, a total thickness of the passivation film (e.g., Tp1+Tp2+Tp3) may be in a range from 0.1 μm to 10,000 μm.

Referring again to FIGS. 1C and 1D, the passivation film 201 may include a plurality of layers of passivation material (dielectric material). In particular, the passivation film 201 may include a first passivation layer 201L1 on the upper surface 140a of the semiconductor dies 140, the upper surface of the upper molding layer 127 and the upper surface of the semiconductor module underfill layer 129. The first metal film 215 of the second capacitor 210B (and the first metal film 211 of the first capacitor 210A) may be formed on an upper surface of the first passivation layer 201L1. The first upper via 211V may be formed in the first passivation layer 201L1.

The passivation film 201 may also include a second passivation layer 201L2 formed on an upper surface of the first passivation layer 102L1 and on the first metal film 215 of the second capacitor 210B (and on the first metal film 211 of the first capacitor 210A). The second metal film 216 of the second capacitor 210B (and the second metal film 212 of the first capacitor 210A) may be formed on an upper surface of the second passivation layer 202L1. The second passivation layer 201L2 may separate the first metal film 215 from the second metal film 216 (and the first metal film 211 from the second metal film 212) and may serve as a charge separating layer that may contain an electric field in the backside capacitor 210. The second upper via 212V may be formed in the second passivation layer 201L2 and the first passivation layer 201L1. The passivation film 201 may also include a third passivation layer 201L3 formed on the second passivation layer 201L2 and on the second metal film 216 of the second capacitor 210B (and the second metal film 212 of the first capacitor 210A).

Referring again to FIG. 1E, the upper molding layer 127 may be formed around an entirety of the semiconductor dies 140 and the semiconductor module underfill layer 129. The semiconductor module 120 may have a substantially rectangular shape in the top-down view. A length of the semiconductor module 120 in the x-direction may be greater than a length of the semiconductor module 120 in the y-direction. A length of the first semiconductor die 141 in the x-direction may be less than a length in the first semiconductor die 141 in the y-direction. A length of the second semiconductor die 142 in the x-direction may be less than a length in the second semiconductor die 142 in the y-direction.

As illustrated in FIG. 1E, a location of the semiconductor dies 140 may be substantially offset from a center of the upper molding layer 127 (e.g., from a center of the semiconductor module 120). This may allow the upper molding layer 127 to accommodate one or more of the TMVs in the connecting structures 230 (e.g., first TMV 231, second TMV 232, etc.) of the charge storing structure 200.

The upper molding layer 127 may have a first side 127a and a second side 127b opposite the first side 127a. The upper molding layer 127 may also have a third side 127c and a fourth side 127d opposite the third side 127c. A distance D1 in the y-direction between a side of the first semiconductor die 141 and the first side 127a of the upper molding layer 127 may be greater than a distance D2 in the y-direction between an opposite side of the first semiconductor die 141 and the second side 127b of the upper molding layer 127. A distance D3 in the x-direction between a side of the second semiconductor die 142 and the third side 127c of the upper molding layer 127 may be greater than a distance D4 in the x-direction between an opposite side of the outermost first semiconductor die 141 and the fourth side 127d of the upper molding layer 127.

Referring again to FIG. 1F, the passivation film 201 of the backside capacitor 210 is omitted for ease of understanding. However, an outer perimeter of the passivation film 201 may be substantially coextensive with an outer perimeter of the upper molding layer 127. A location of the outer perimeter of the passivation film is indicated by the dashed line in FIG. 1F.

As illustrated in FIG. 1F, the backside capacitor 210 may include a total of three capacitors. The backside capacitor 210 may include the first capacitor 210A on the more centrally located first semiconductor die 141. The backside capacitor 210 may also include two second capacitors 210B on the two second semiconductor dies 142, respectively.

The first capacitor 210A may cover a substantial entirety of the more centrally located first semiconductor die 141. An outer perimeter of the first capacitor 210A may be substantially coextensive with an outer perimeter of the more centrally located first semiconductor die 141. However, the first metal film 211 may include an overhang portion 211o that extends by an overhang distance OD1 beyond an edge of the first semiconductor die 141 toward the first side 127a of the upper molding layer 127. The first upper via 211V may connect to a bottom side of the overhang portion 211o of the first metal film 211. The second metal film 212 may include an overhang portion 212o that extends by an overhang distance OD2 beyond an edge of the first metal film 211 toward the first side 127a of the upper molding layer 127. The second upper via 212V may connect to a bottom side of the overhang portion 212o of the second metal film 212. In at least one embodiment, the overhang distance OD1 may be substantially the same as the overhang distance OD2. In at least one embodiment, the overhang distance OD1 may be at least 10% greater than a diameter of the first upper via 211V. In at least one embodiment, the overhang distance OD2 may be at least 10% greater than a diameter of the second upper via 212V.

Each of the second capacitors 210B may cover a substantial entirety of the respective second semiconductor die 142. An outer perimeter of the second capacitor 210B may be substantially coextensive with an outer perimeter of the second semiconductor die 142. However, the first metal film 215 may include an overhang portion 215o that extends by an overhang distance OD5 beyond an edge of the second semiconductor die 142 toward the third side 127c of the upper molding layer 127. The first upper via 215V may connect to a bottom side of the overhang portion 215o of the first metal film 215. The second metal film 216 may include an overhang portion 216o that extends by an overhang distance OD6 beyond an edge of the first metal film 215 toward the third side 127c of the upper molding layer 127. The second upper via 216V may connect to a bottom side of the overhang portion 216o of the second metal film 216. In at least one embodiment, the overhang distance OD5 may be substantially the same as the overhang distance OD6. In at least one embodiment, the overhang distance OD5 may be at least 10% greater than a diameter of the first upper via 215V. In at least one embodiment, the overhang distance OD6 may be at least 10% greater than a diameter of the second upper via 216V.

In at least one embodiment, each metal film of the pair of parallel metal films in each of the three capacitors (the first capacitor 210A and the two second capacitors 210B) may be substantially aligned with its respective semiconductor die. Each metal film of the pair of parallel metal films in each of the three capacitors may have an area substantially the same as an area of the upper surface of its respective semiconductor die. However, a size and location of the capacitors in the backside capacitor 210 is not necessarily restricted to size and location of the semiconductor dies. In at least one embodiment, a total area of the backside capacitor (e.g., a total area of the first capacitor 210A and the two second capacitors 210B) is in a range from 10% to 100% of an area of the semiconductor module.

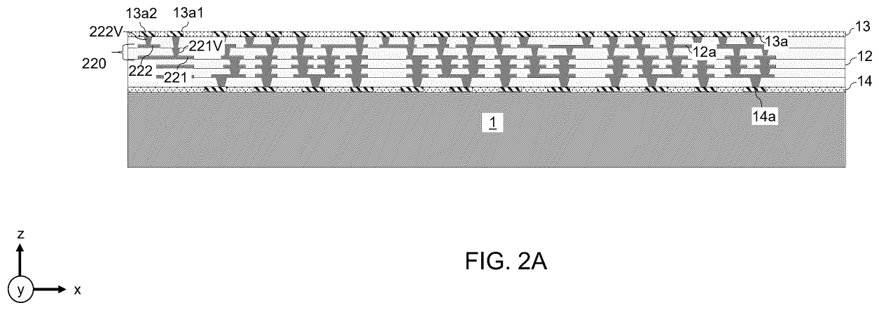

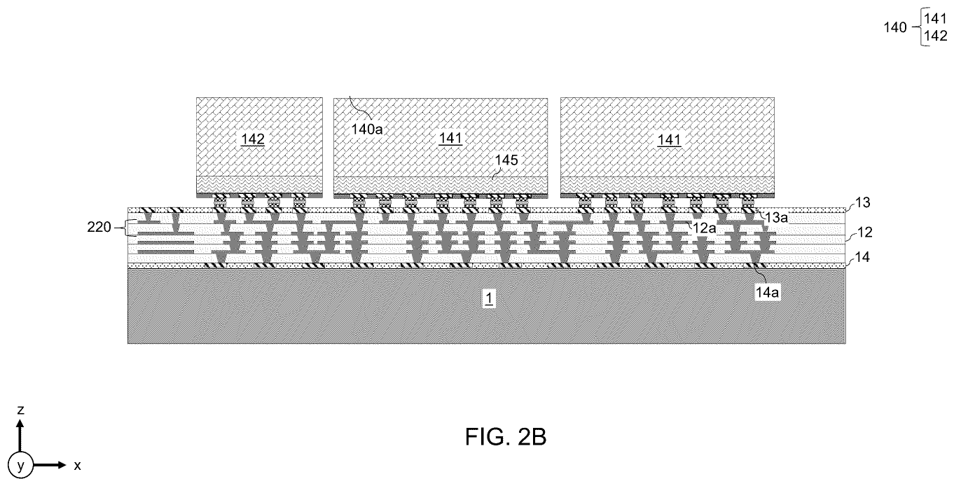

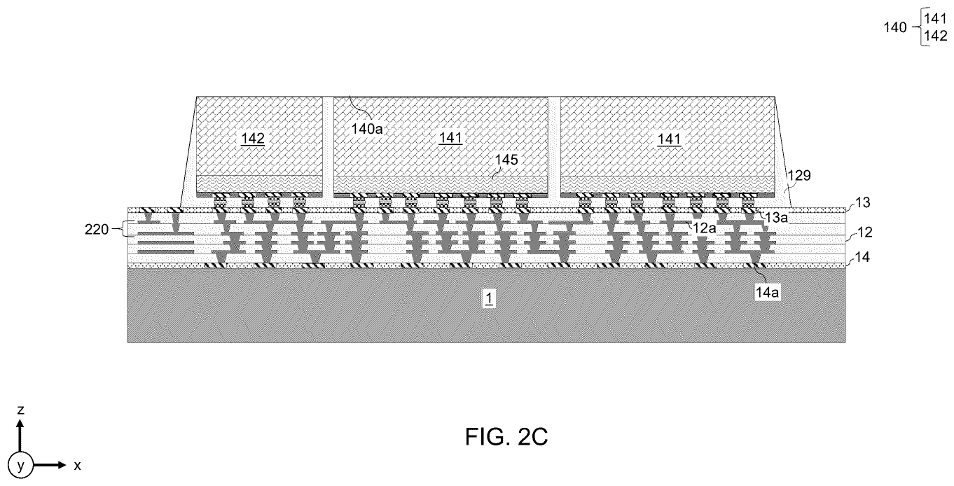

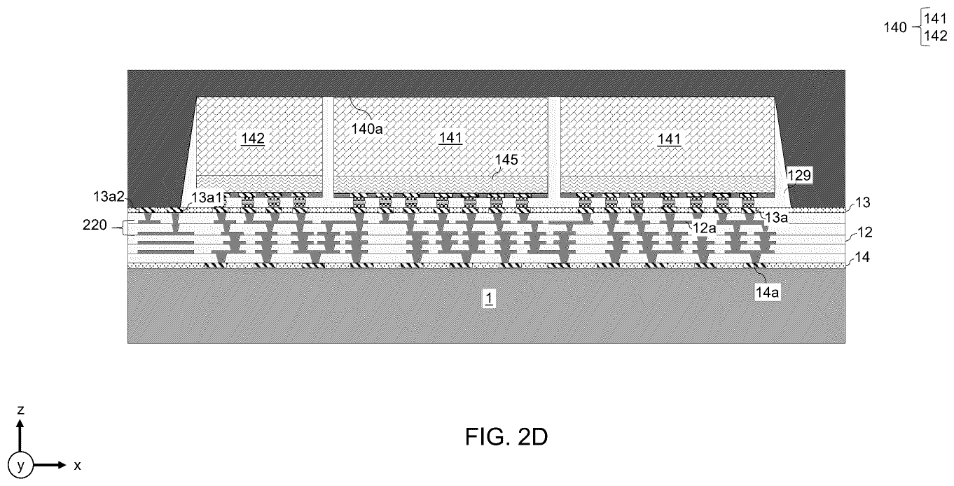

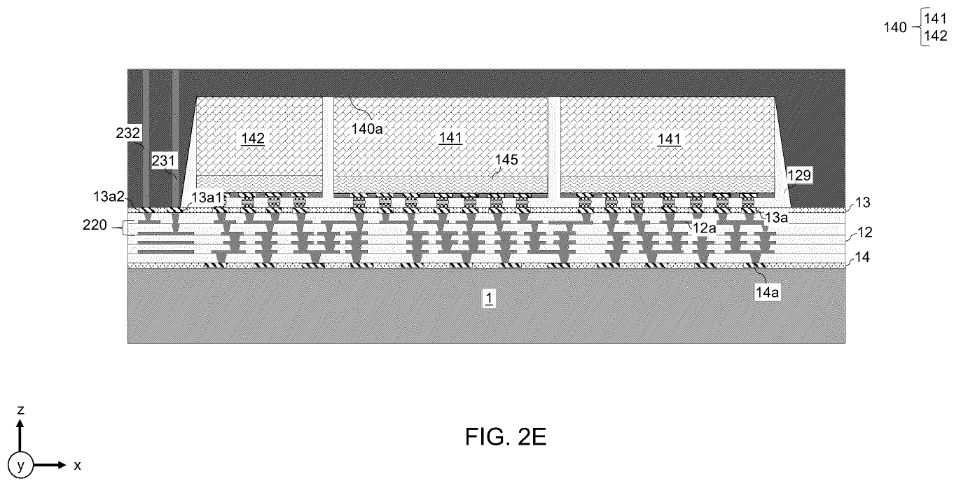

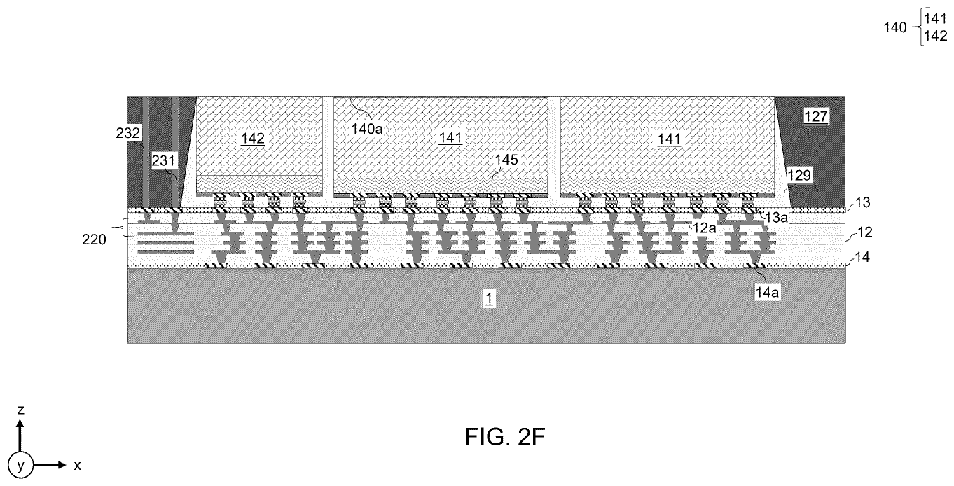

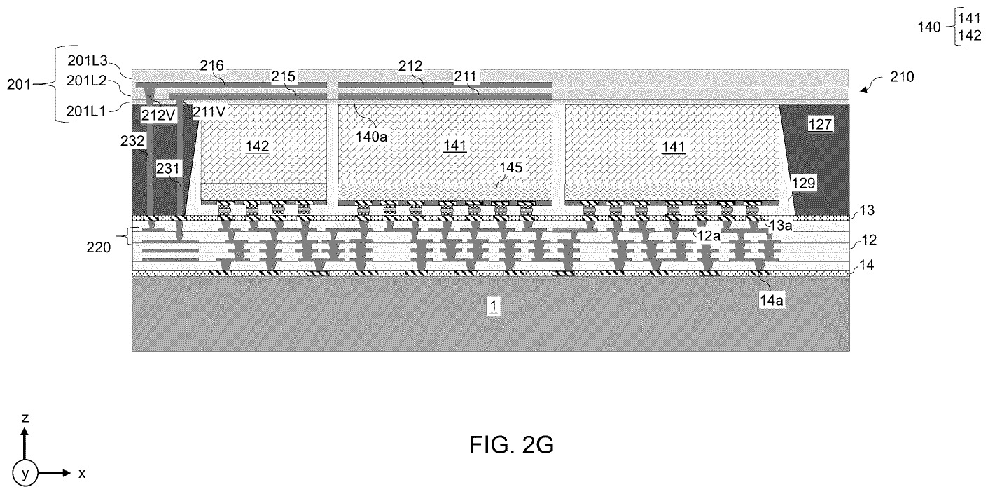

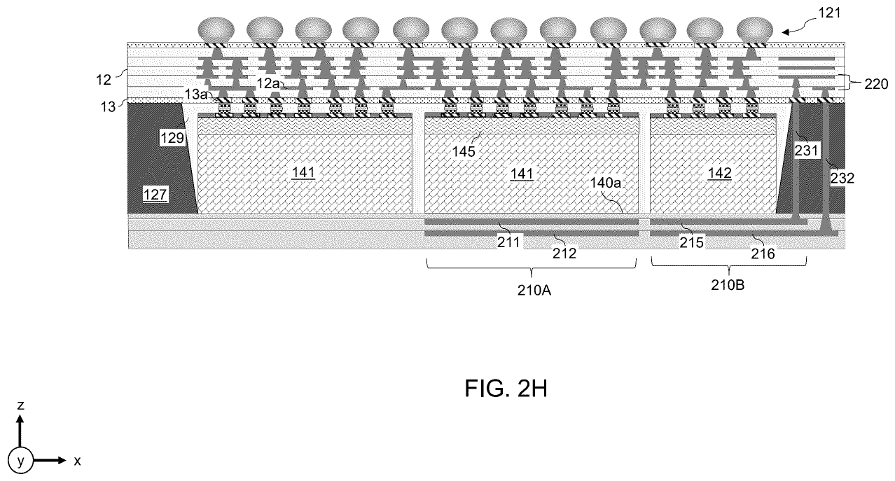

FIGS. 2A-2F illustrate various intermediate structures in a method of forming the package module 120 according to one or more embodiments. FIG. 2A is a vertical cross-sectional view of an intermediate structure including an interposer 10 (e.g., organic interposer) formed on a carrier substrate 1 (e.g., carrier wafer) according to an embodiment of the present invention. The carrier substrate 1 may be a circular wafer or a rectangular wafer. The lateral dimensions (such as the diameter of a circular wafer or a side of a rectangular wafer) of the carrier substrate 1 may be in a range from 100 mm to 500 mm, such as from 200 mm to 400 mm, although lesser and greater lateral dimensions may also be used. The carrier substrate 1 may include a semiconductor substrate, an insulating substrate, or a conductive substrate. The carrier substrate 1 may be transparent or opaque. The thickness of the carrier substrate 1 may be sufficient to provide mechanical support to an array of interposers to be formed thereupon. For example, the thickness of the carrier substrate 1 may be in a range from 60 microns to 1 mm, although lesser and greater thicknesses may also be used.

An adhesive layer (not shown) may be applied to the top surface of the carrier substrate 1. In one embodiment, the carrier substrate 1 may include an optically transparent material such as glass or sapphire. In this embodiment, the adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

The lower bonding pads 14a may be formed on the adhesive layer. The lower bonding pads 14a may include any metallic material that may be bonded to a solder material. The lower bonding pads 14a may be formed by depositing (e.g., by CVD, PVD or other suitable deposition technique) one or more metal layers including a metal, metal alloys, and/or other metal-containing compounds (e.g., Cu, Al, Mo, Co, Ru, W, TiN, TaN, WN, etc.). The metal layer may then be patterned by a photolithographic process so as to form the lower bonding pads 14a. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

In at least one embodiment, the lower bonding pads 14a may include an underbump metallurgy (UBM) layer stack deposited over the adhesive layer. The order of material layers within the UBM layer stack may be selected such that solder material portions may be subsequently bonded to portions of the bottom surface of the UBM layer stack. Layer stacks that may be used for the UBM layer stack include, but are not limited to, stacks of Cr/Cr—Cu/Cu/Au, Cr/Cr—Cu/Cu, TiW/Cr/Cu, Ti/Ni/Au, and Cr/Cu/Au. Other suitable materials are within the contemplated scope of disclosure. The thickness of the UBM layer stack may be in a range from 5 microns to 60 microns, such as from 10 microns to 30 microns, although lesser and greater thicknesses may also be used. A photoresist layer may be applied over the UBM layer stack, and may be lithographically patterned to form an array of discrete patterned photoresist material portions. An etch process may be performed to remove unmasked portions of the UBM layer stack. The etch process may be an isotropic etch process or an anisotropic etch process. Remaining portions of the UBM layer stack may form the lower bonding pads 14a. In at least one embodiment, the lower bonding pads 14a may be arranged as a two-dimensional array, which may be a two-dimensional periodic array such as a rectangular periodic array. In at least one embodiment, the lower bonding pads 14a may be formed as a base for supporting controlled collapse chip connection (C4) bump structures.

The lower passivation layer 14 may then be formed on the board-side surface of the interposer 10 and over the lower bonding pads 14a. The lower passivation layer 14 may be formed by depositing (e.g., by CVD, PVD or other suitable deposition technique) one or more layers of passivation material including silicon oxide, silicon nitride, low-k dielectric materials such as carbon-doped oxides, extremely low-k dielectric materials such as porous carbon doped silicon dioxide, a combination thereof or other suitable material. The passivation material may then be planarized (e.g., by wet etching, drying etching, etc.) so as to form the lower passivation layer 14.

A plurality of dielectric layers 12 and plurality of redistribution layers 12a may then be alternately formed on the lower passivation layer 14 and lower bonding pads 14a. It should be noted that although FIG. 2A illustrates five dielectric layers 12 and four redistribution layers 12a, more or fewer dielectric layers 12 and redistribution layers 12a are contemplated by the present disclosure.

Each dielectric layer 12 may each be formed, for example, by depositing (e.g., by CVD, PVD or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 microns to 60 microns, although lesser and greater thicknesses may also be used. The dielectric layer 12 may then be patterned by a photolithographic process to form via holes in the dielectric layer 12. The photolithographic process may include forming a patterned photoresist mask (not shown) on the layer of dielectric material, and etching (e.g., wet etching, dry etching, etc.) the exposed upper surface of the dielectric material through openings in the photoresist mask. The photoresist mask may be subsequently removed by ashing, dissolving the photoresist mask or by consuming the photoresist mask during the etch process.

A redistribution layer 12a (e.g., metal traces and metal vias) may then be formed on the dielectric layer 12. The redistribution layer 12a may be formed, for example, by depositing (e.g., by CVD, PVD or other suitable deposition technique) one or more layers of metal material such as copper, aluminum, nickel, titanium, a combination thereof or other suitable metals, on the dielectric layer 12 and in the vias holes formed by patterning the dielectric layer 12. The redistribution layer 12a may then be patterned by a photolithographic process. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

As illustrated in FIG. 2A, the first distribution line 221 and second distribution line 222 of the distribution layer structure 220 may be formed in the dielectric layers 12 along with the forming of the redistribution layers 12a. In addition, the first lower vias 221V and second lower vias 222V of the connecting structure 230 may also be formed in the dielectric layers 12 along with the forming of the redistribution layers 12a. That is, the same processing steps used to form the redistribution layers 12a may be used to form the first distribution line 221, second distribution line 222, first lower vias 221V and second lower vias 222V. In at least one embodiment, the first distribution line 221, second distribution line 222, first lower vias 221V and second lower vias 222V are included as part of the redistribution layers 12 (e.g., RDL structure) in the interposer 10.

As further illustrated in FIG. 2A, the upper bonding pads 13a may then be formed on the uppermost dielectric layer 12. The upper bonding pads 13a may be formed by a process similar to that described above with respect to the lower bonding pads 14a. Further, the first upper bonding pad 13a1 and second upper bonding pad 13a2 may also be formed on the uppermost dielectric layer 12 along with the forming of the other upper bonding pads 13a of the interposer 10. That is, the same processing steps used to form the upper bonding pads 13a may be used to form the first upper bonding pad 13a1 and second upper bonding pad 13a2 of the connecting structure 230.

The upper passivation layer 13 may then be formed on the uppermost dielectric layer 12 and the upper bonding pads 13a. The upper passivation layer 13 may also be formed on the first upper bonding pad 13a1 and second upper bonding pad 13a2 of the connecting structure 230. The upper passivation layer 13 may be formed by a process similar to that described above with respect to the lower passivation layer 14.

FIG. 2B is a vertical cross-sectional view of an intermediate structure including the first semiconductor die 141 and the second semiconductor die 142 according to one or more embodiments. The first semiconductor die 141 and second semiconductor die 142 may be placed on the interposer module 10, for example, by using a electromechanical pick-and-place (PNP) machine.

Each of the first semiconductor die 141 and second semiconductor die 142 may be bonded to a respective subset of the upper bonding pads 13a. The first semiconductor die 141 and second semiconductor die 142 may be electrically coupled to each other by one or more redistribution layers 12a in the interposer 10. In at least one embodiment, the first distribution line 221 and second distribution line 222 of the distribution structure 220 may be electrically isolated from the redistribution layers 12a in the interposer 10 and, therefore, electrically isolated from the semiconductor dies 140. In at least one embodiment, the first distribution line 221 and second distribution line 222 of the distribution structure 220 may be electrically coupled to at least some portion of the redistribution layers 12a in the interposer 10 and, therefore, electrically coupled to the semiconductor dies 140.

Each of the first semiconductor die 141 and second semiconductor die 142 may be bonded to the interposer 10 by one or more microbumps 128. In at least one embodiment, the microbumps 128 may include a two-dimensional array of microbumps 128, and each of the first semiconductor die 141 and second semiconductor die 142 may be attached to the upper bonding pads 13a by C2 bonding, (e.g., solder bonding). A C2 bonding process that reflows the solder portions of the microbumps 128 may be performed after bump structures of the semiconductor dies (e.g., first semiconductor die 141 and second semiconductor die 142) are disposed over the upper bonding pads 13a.

FIG. 2C is a vertical cross-sectional view of an intermediate structure including the semiconductor module underfill layer 129 according to one or more embodiments. The semiconductor module underfill layer 129 may be applied by depositing and/or injecting an epoxy-based polymeric material onto the interposer 10. The epoxy-based polymeric material may be applied on the interposer 10 so as to be formed under and around the microbumps 128. The semiconductor module underfill layer 129 may then be cured, for example, in a box oven for about 90 minutes at about 150° C. to provide the semiconductor module underfill layer 129 with a sufficient stiffness and mechanical strength.

FIG. 2D illustrates a vertical cross-sectional view of an intermediate structure including the upper molding layer 127 according to one or more embodiments. The upper molding layer 127 may be formed by dispensing a liquid molding material (e.g., epoxy molding material) onto the intermediate structure of FIG. 2E by a suitable dispensing tool. The upper molding layer 127 may be dispensed onto the intermediate structure so as to have a height greater than a height of the upper surface 140a of the semiconductor dies 140 (the first semiconductor die 141 and second semiconductor die 142).

In at least one embodiment, a dispensing of the molding material may be automated. In particular, various aspects of the dispensing process may be computer-controlled by a control system (e.g., electronic control system; central processing unit (CPU)). In at least one embodiment, a beginning of the dispensing of the molding material, a flow rate of the dispensing of the molding material, and a stopping of the dispensing of the molding material may be controlled by the control system. The control system may be programmed, for example, to dispense a predetermined amount of the molding material based on various input parameters. The input parameters may include, for example, a volume of the space around the interposer 10, a size of the interposer 10, a size of the first semiconductor die 141, a size of the second semiconductor die 142, etc.

In at least one embodiment, the molding material of the upper molding layer 127 may include a capillary material (e.g., capillary underfill type material). The molding material may have a low viscosity. In particular, the viscosity may be less than about 5,000 cP at 10 rpm. In at least one embodiment, the molding material may include a low-viscosity suspension of thermally conductive but electrically non-conductive material (e.g., oxide filler) in prepolymer. The low viscosity may help to facilitate transport of the molding material around the first semiconductor die 141 and second semiconductor die 142. The low viscosity may also help to avoid the formation of voids in the upper molding layer 127. In at least one embodiment, the upper molding layer 127 may be substantially free of voids.

FIG. 2E illustrates a vertical cross-sectional view of an intermediate structure including the first TMV 231 and second TMV 232, according to one or more embodiments. After the upper molding layer 127 has been adequately cured, the first TMV 231 and second TMV 232 of the connecting structure 230 may be formed in the upper molding layer 127. First, openings for the first TMV 231 and second TMV 232 may be formed in the upper molding layer 127.

In at least one embodiment, the openings may be formed by a laser drilling process. In the laser drilling process, a suitable laser such as a CO₂ layer or UV laser may be positioned over the intermediate structure. A focus of the laser may be directed to the desired location of the first TMV 231 and second TMV 232. The laser may then be activated in order to drill openings in the upper molding layer 127 having a size and depth corresponding to a size and depth of the first TMV 231 and second TMV 232. The spot size, pulse duration, and energy density of the laser may be carefully controlled to achieve the desired depth and diameter of the opening without damaging the surrounding material. The laser may be pulsed onto the upper molding layer 127, where it rapidly heats and vaporizes the material in the targeted area. The laser may be programmed to drill to a specific depth (e.g., a thickness of the molding material), ensuring the opening reaches the first upper bonding pad 13a1 and second upper bonding pad 13a2.

After the openings for the first TMV 231 and second TMV 232 have been formed, the first TMV 231 and second TMV 232 may be formed in the openings. In at least one embodiment, the first TMV 231 and second TMV 232 may be formed by an electroplating process in which the first TMV 231 and second TMV 232 are grown in the openings. In the electroplating process, the first upper bonding pad 13a1 and second upper bonding pad 13a2 may be used as seed layers for initiating the growth of the first TMV and second TMV 232 by the electroplating process.

FIG. 2F illustrates a vertical cross-sectional view of an intermediate structure after a planarization process, according to one or more embodiments. After the first TMV 231 and second TMV 232 have been formed (e.g., by the electroplating process), the upper molding layer 127, first TMV 231 and second TMV 232 may be planarized by a planarization process. The planarization process may be used so to make each of the upper surface of the upper molding layer 127, the upper surface of the first TMV 231 and the upper surface of the second TMV 232 to be substantially coplanar with the upper surface of the first semiconductor die 141 and second semiconductor die 142. The upper molding layer 127, first TMV 231 and second TMV 232 may be planarized, for example, by grinding, chemical mechanical polishing (CMP) or other suitable planarization technique.

FIG. 2G illustrates a vertical cross-sectional view of an intermediate structure including the backside capacitor 210, according to one or more embodiments. The backside capacitor 210 may be formed, for example, in a manner similar to the manner of forming the dielectric layers 12 and redistribution layers 12a of the interposer 10. In particular, the first passivation layer 201L1 may be formed by a suitable deposition process (e.g., by CVD, PVD or other suitable deposition technique) on the upper surface of the upper molding layer 127 and the upper surface 140a of the semiconductor dies 140. The first passivation layer 201L1 may be formed, for example, by depositing a layer of dielectric polymer material such as SiNₓ, SiOₓ, polybenzoxazole (PBO), polyimide (PI), Ajinomoto Build-up Film (ABF) and bismaleimide triazine (BT) or benzocyclobutene (BCB). Other suitable materials are within the contemplated scope of disclosure. The dielectric polymer material may then be patterned by a photolithographic process to form a via hole for the first upper via 211V in the first passivation layer 201L1. The photolithographic process may include forming a patterned photoresist mask (not shown) on the layer of dielectric polymer material, and etching (e.g., wet etching, dry etching, etc.) the exposed upper surface of the dielectric polymer material through openings in the photoresist mask. The photoresist mask may be subsequently removed by ashing, dissolving the photoresist mask or by consuming the photoresist mask during the etch process.

The first metal film 211 and the first metal film 215 may then be formed on the first passivation layer 201L1. The first metal film 211 and the first metal film 215 may be formed, for example, by depositing (e.g., by CVD, PVD or other suitable deposition technique) one or more layers of metal material such as copper, aluminum, nickel, titanium, a combination thereof or other suitable metals, on the first passivation layer 201L1 and in the vias holes formed by patterning the first passivation layer 201L1. The metal material may then be patterned by a photolithographic process to form the first upper via 211 V, the first metal film 211 and the first metal film 215. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

Similar processes may be performed to complete the formation of the backside capacitors 210. In particular, the second passivation layer 201L2 may be formed by a suitable deposition process on the first passivation layer 201L1 the first metal film 211 and the first metal film 215. An opening for the second upper via 212V may be formed (e.g., by a photolithographic process) in the second passivation layer 201L2 and first passivation layer 201L1. A metal material may be deposited on the second passivation layer 201L2 and patterned (e.g., by photolithographic process) to form the second upper via 212V, second metal film 212 and second metal film 216. The third passivation layer 201L3 may then be formed (e.g., by suitable deposition process) on the second passivation layer 201L2, the second metal film 212 and the second metal film 216.

FIG. 2H illustrates a vertical cross-sectional view of an intermediate structure including the plurality of C4 bumps 121, according to one or more embodiments. After the backside capacitor 210 is formed, the carrier substrate 1 may be detached from the interposer 10. The carrier substrate 1 may be detached from the interposer 10, for example, by deactivating the adhesive layer (not shown) adhering the carrier substrate to the interposer 10. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

The plurality of C4 bumps 121 may then be formed on the intermediate structure. The C4 bumps 121 may include, for example, solder balls formed on the lower bonding pads 14a, for example, by an electroplating process. The plurality of C4 bumps 121 may contact the lower bonding pads 14a through openings in the lower passivation layer 14. In at least one embodiment, one or more underbump metallization (UBM) layers (not shown) may be formed on the lower bonding pads 14a. The plurality of C4 bumps 121 may then be formed so as to contact the lower bonding pads 14a through the UBM layers.

A plurality of the semiconductor modules 120 may be formed concurrently on the interposer 10 (e.g., interposer wafer) in a wafer-level process. After the forming of the C4 bumps 121, a singulation process may be performed in order to singulate the semiconductor modules 120. The singulation process may be performed, for example, by using a dicing saw to saw the interposer 10 (and the molding material 127 and passivation film 201 of the backside capacitor 210 formed thereon) along dicing lines that are located outside the first capacitor 210A and second capacitors 210B. In particular, the dicing lines may be located sufficiently distant (e.g., greater than 0.8 mm) from the first capacitor 210A and second capacitors 210B.

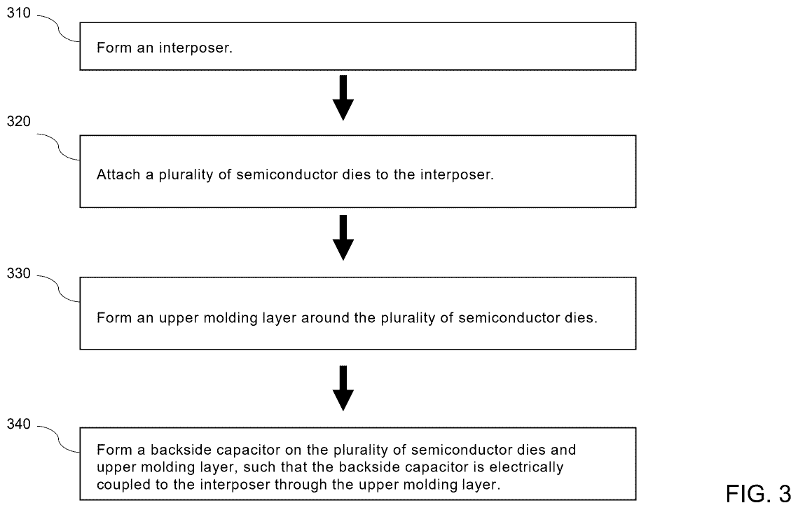

FIG. 3 is a flow chart illustrating a method of making a semiconductor module according to one or more embodiments. Step 310 includes forming an interposer. Step 320 includes attaching a plurality of semiconductor dies to the interposer. Step 330 includes forming an upper molding layer around the plurality of semiconductor dies. Step 340 includes forming a backside capacitor on the plurality of semiconductor dies and upper molding layer, such that the backside capacitor is electrically coupled to the interposer through the upper molding layer.

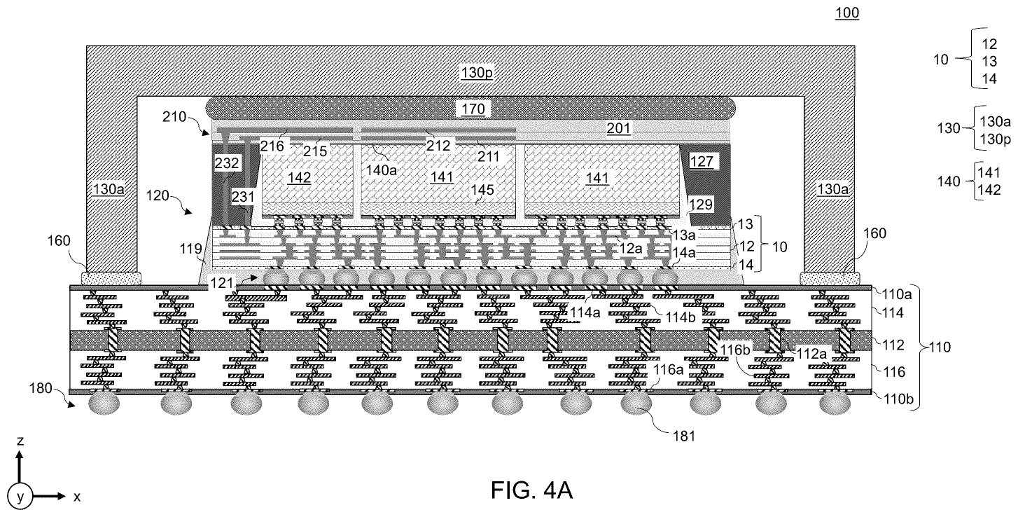

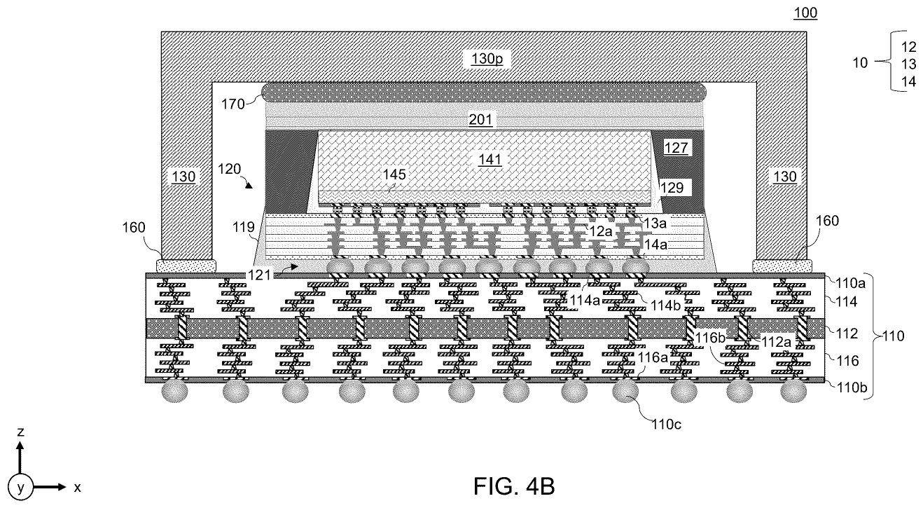

FIGS. 4A and 4B are vertical cross-sectional views of a package structure 100 including the semiconductor module 120 according to one or more embodiments. FIG. 4A is a vertical cross-sectional view (front view) of the package structure 100 according to one or more embodiments. FIG. 4B is a vertical cross-sectional view (side view) of the package structure 100 according to one or more embodiments.

As illustrated in FIG. 4A, the package structure 100 may include a package substrate 110, the semiconductor module 120 including the backside capacitor 210 on the package substrate 110, and a package lid 130 on the semiconductor module 120. The package lid 130 may include a package lid plate portion 130p over the semiconductor module 120 and a package lid foot portion 130a attached to the package substrate 110.

The package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclobutene (BCB) polymer, or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. The package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may be connected to the package substrate upper bonding pads 114a and the through vias 112a in the core 112. The metal interconnect structures 114b may include metal layers (e.g., copper traces) and metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate upper passivation layer 110a may be formed on the chip-side surface of the package substrate upper dielectric layer 114. The package substrate upper passivation layer 110a may partially cover the package substrate upper bonding pads 114a. The upper passivation layer 110a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on a lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. In particular, the package substrate lower bonding pads 116a may be exposed on the board-side surface of the package substrate lower dielectric layer 116. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include metal layers (e.g., copper traces) and metal vias connecting the metal layers. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate lower passivation layer 110b may be formed on the board-side surface of the package substrate lower dielectric layer 116. The package substrate lower passivation layer 110b may partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) 180 including a plurality of solder balls 181 may be formed on the board-side surface of the package substrate lower dielectric layer 116. The solder balls 181 may allow the package structure 100 to be securely mounted on a substrate such as a printed circuit board (PCB) and electrically coupled to the PCB substrate. The solder balls 181 may contact the package substrate lower bonding pads 116a, respectively. The solder balls 181 may therefore be electrically connected to the package substrate upper bonding pads 114a by way of metal interconnect structures 116b, the through vias 112a and the metal interconnect structures 114b.

The semiconductor module 120 may be mounted on the package substrate 110. In particular, the C4 bumps 121 of the semiconductor module 120 may be attached to the package substrate upper bonding pads 114a of the package substrate 110. As illustrated in FIG. 4A, the package substrate 110 may have a length in the x-direction that is greater than a length of the semiconductor module 120 in the x-direction. The package substrate 110 may also have a width in the y-direction that is greater than a width of the semiconductor module 120 in the y-direction.

A package underfill layer 119 may be formed on the package substrate 110 under and around the semiconductor module 120. The package underfill layer 119 may also be formed around the C4 bumps 121. The package underfill layer 119 may thereby securely fix the semiconductor module 120 to the package substrate 110. The package underfill layer 119 may be formed of material similar to a material of the semiconductor module underfill layer 129. In at least one embodiment, the package underfill layer 119 may be formed of an epoxy-based polymeric material.

The package structure 100 may further include a thermal interface material (TIM) layer 170 on the semiconductor module 120. The TIM layer 170 may be located on the upper surface of the backside capacitor 210. The TIM layer 170 may include, for example, a grease type TIM, a paste type TIM, film type TIM, a gel type TIM, graphite film TIM, a liquid metal TIM (e.g., a gallium-rich TIM), a PCM type TIM, etc. In at least one embodiment, the TIM layer 170 may include a low-melting-temperature (LMT) metal TIM. The PCM type TIM may include, for example, a polymer-based PCM TIM. The PCM type TIM may improve void and delamination issues, enhance thermal contact resistance and improve thermal performance in a package structure 100. In at least one embodiment, the PCM type TIM may change its phase from solid to high viscosity semi liquid around 60° C. In at least one embodiment, the TIM layer 170 may include a gallium base, indium base, silver base, solder base, etc. Other types TIMs in the TIM layer 170 are within the contemplated scope of this disclosure.

The TIM layer 170 may be formed on the backside capacitor 210 to dissipate heat generated during operation of the semiconductor module 120 (e.g., operation of the semiconductor dies 140). The TIM layer 170 may be attached to the backside capacitor 210, for example, by a thermally conductive adhesive. The TIM layer 170 may have a low bulk thermal impedance and high thermal conductivity. The bond-line-thickness (BLT) (e.g., a distance between the package lid 130 and the backside capacitor 210) may be less than about 100 μm, although greater or lesser distances may be used.

The package lid 130 may be located over the semiconductor module 120 and connected to the package substrate 110. The package lid 130 may include a package lid plate portion 130p formed on the TIM layer 170 over the semiconductor module 120. The TIM layer 170 may be compressed between the underside of the package lid plate portion 130p and the backside capacitor 210. The package lid 130 may also include a package lid foot portion 130a located around an outer periphery of the package lid plate portion 130p. The package lid foot portion 130a may be fixed to the package substrate 110 by an adhesive layer 160.

The package lid 130 may be formed, for example, of metal, ceramic or polymer material. In at least one embodiment, a material of the package lid 130 may include copper with a nickel coating surface. The nickel coating surface may have a thickness in a range of 1 μm to 10 μm. The package lid plate portion 130p may have a plate shape (e.g., planar shape) and be substantially parallel to an upper surface of the package substrate 110. The package lid plate portion 130p may extend, for example, in an x-y plane in FIG. 4A. The package lid plate portion 130p may include an outer sidewall that is substantially aligned with an outer sidewall of the package lid foot portion 130a. A center of package lid plate portion in the x-y plane may be substantially aligned in the z-direction with a center of the semiconductor module 120 in the x-y plane. An upper surface of the package lid plate portion 130p may be substantially parallel to the underside of the package lid plate portion 130p.

The adhesive layer 160 may be formed on the package substrate 110 near the sidewall of the semiconductor module 120. The adhesive layer 160 may bond the package lid foot portion 130a to package substrate 110. A thickness of the adhesive layer 160 may be in a range from 50 μm to 200 μm. The adhesive layer 160 may include, for example, a silicone adhesive (e.g., containing aluminum oxide, zinc oxide, resin, etc.) or an epoxy adhesive. Other suitable adhesives may be used. The adhesive layer 160 may contact the backside metal layer or the recessed upper surface of the upper molding layer 127.

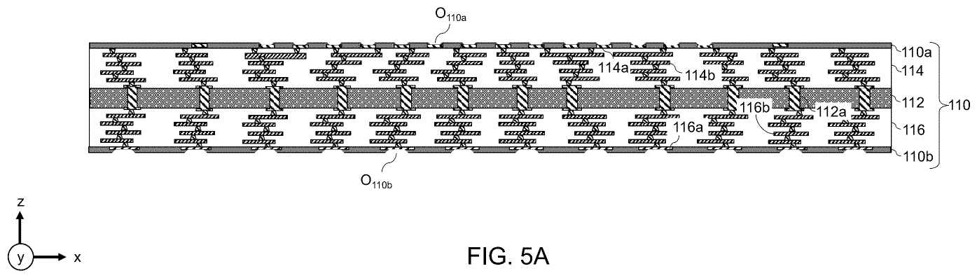

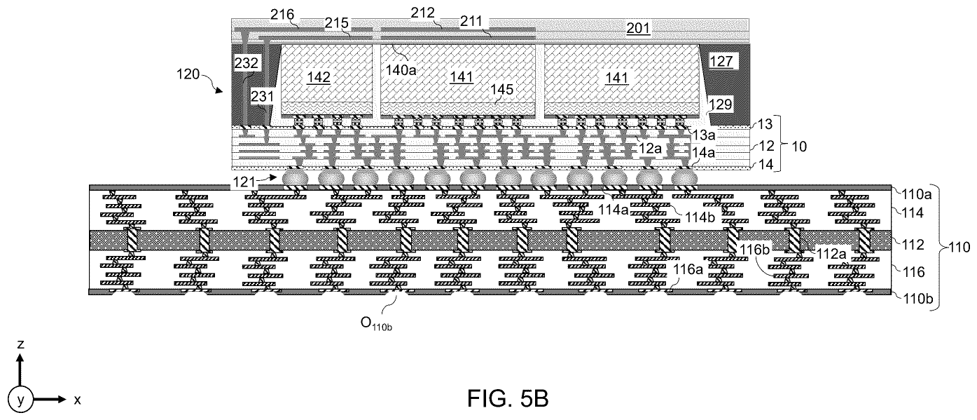

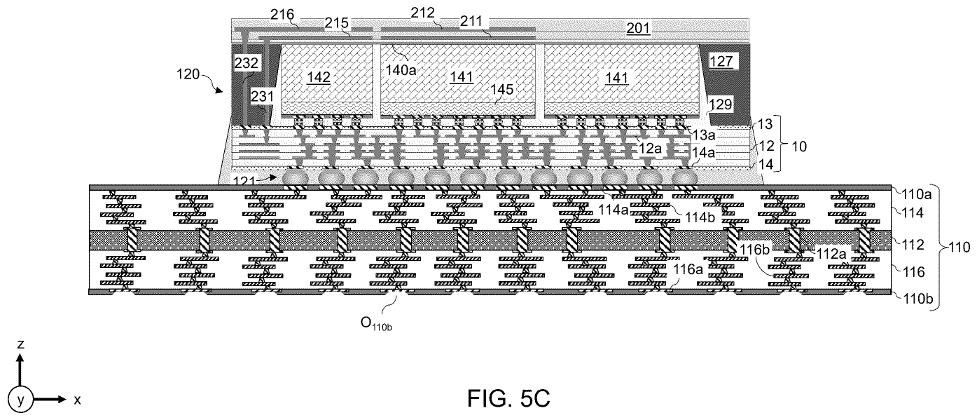

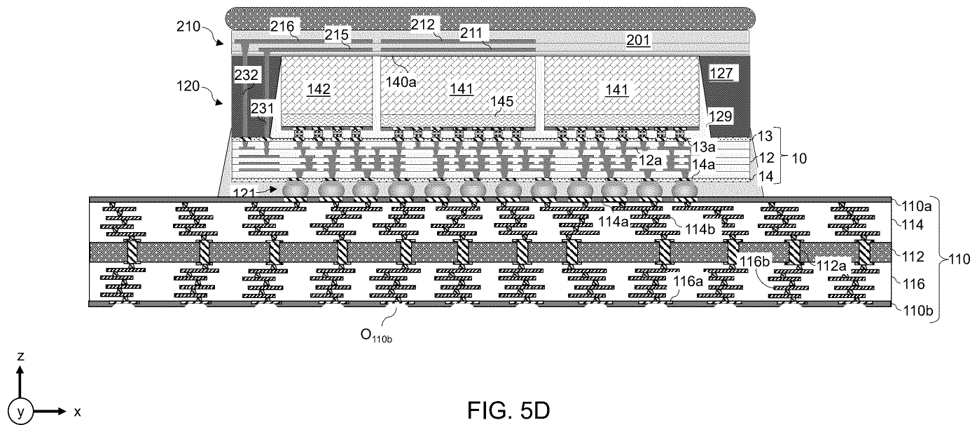

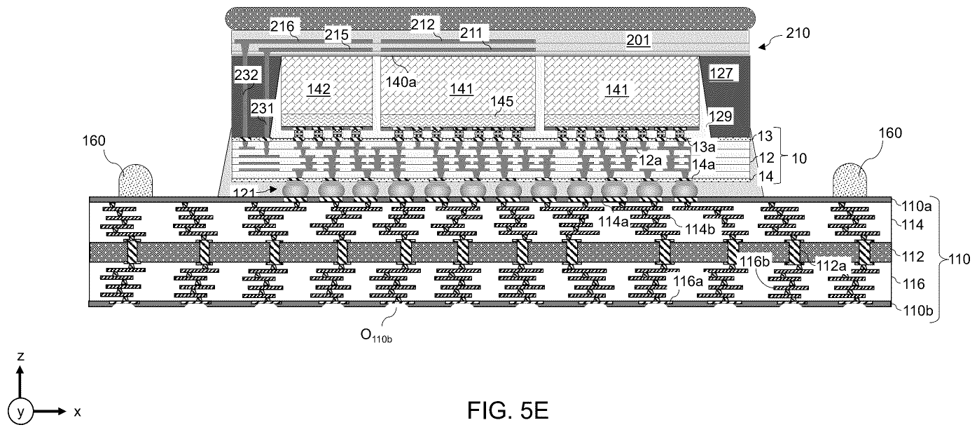

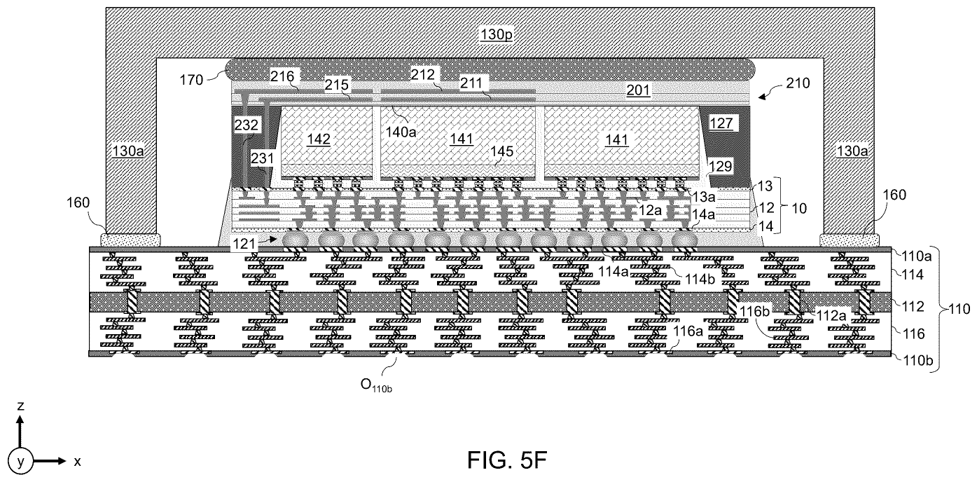

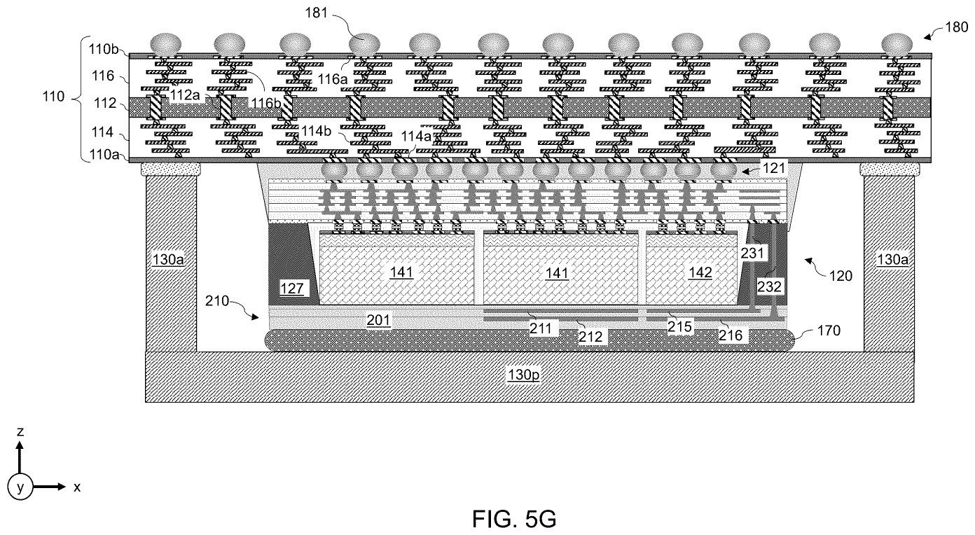

FIGS. 5A-5G illustrate various intermediate structures in a method of forming the package structure 100 according to one or more embodiments. FIG. 5A is a vertical cross-sectional view of an intermediate structure including the package substrate 110 having package substrate upper bonding pads 114a and package substrate lower bonding pads 116a, according to one or more embodiments. The package substrate 110 including the core 112, the package substrate upper dielectric layer 114, and the package substrate lower dielectric layer 116 may be provided.

The package substrate upper bonding pads 114a may be formed, for example, on an uppermost dielectric layer of the package substrate upper dielectric layer 114. The package substrate upper bonding pads 114a may be formed to contact the metal interconnect structures 114b. The package substrate upper bonding pads 114a may be formed by depositing a metal layer (e.g., copper, aluminum or other suitable conductive materials) on the upper surface of the package substrate upper dielectric layer 114. The metal layer may then be patterned by etching (e.g., by wet etching, dry etching, etc.) to form the package substrate upper bonding pads 114a. Other suitable metal layer materials and etching processes may be within the contemplated scope of disclosure.

The package substrate lower bonding pads 116a may be formed, for example, on a lowest dielectric layer of the package substrate lower dielectric layer 116. The package substrate lower bonding pads 116a may be formed to contact the metal interconnect structures 116b. The package substrate lower bonding pads 116a may be formed in a manner similar to the manner of forming the package substrate upper bonding pads 114a (e.g., depositing a metal layer, patterning the metal layer by etching, etc.).

After formation, the package substrate upper bonding pads 114a and package substrate lower bonding pads 116a may optionally undergo a surface roughening treatment (e.g., copper zarazara (CZ) treatment). In the surface roughening treatment, a surface of the package substrate upper bonding pads 114a (e.g., a copper surface) and surface of the package substrate lower bonding pads 116a (e.g., a copper surface) may be etched by an organic acid-type microetching solution, to create a super-roughened surface (e.g., copper surface). The uniquely-roughened copper surface topography of the package substrate upper bonding pads 114a and package substrate lower bonding pads 116a may help to achieve a high copper-to-resin adhesion.

The package substrate upper passivation layer 110a and package substrate lower passivation layer 110b may then be formed on the package substrate upper bonding pads 114a and package substrate lower bonding pads 116a, respectively. In at least one embodiment, the package substrate upper passivation layer 110a may include a solder resist layer (e.g., polymer material), also referred to as a solder mask. The package substrate upper passivation layer 110a may also be referred to as the upper solder resist layer 110a, and the package substrate lower passivation layer 110b may also be referred to as the lower solder resist layer 110b.

The package substrate upper passivation layer 110a and package substrate lower passivation layer 110b may be applied concurrently. The package substrate upper passivation layer 110a and package substrate lower passivation layer 110b may be applied, for example, as a liquid photo-imageable film. The liquid photo-imageable film can be applied, for example, by silk-screening or spraying the liquid photo-imageable film onto the surface of the package substrate 110. The liquid photo-imageable film may be applied over the package substrate upper bonding pads 114a and the package substrate lower bonding pads 116a. The package substrate upper passivation layer 110a and package substrate lower passivation layer 110b may alternatively be applied as a dry-film photo-imageable film that may be vacuum-laminated onto the surface of the package substrate 110 and over the package substrate upper bonding pads 114a and package substrate lower bonding pads 116a, respectively. The package substrate upper passivation layer 110a and package substrate lower passivation layer 110b may alternatively or additionally be formed, for example, by chemical vapor deposition (CVD), physical vapor deposition (PVD), spin coating, lamination or other suitable deposition technique.

The package substrate upper passivation layer 110a and package substrate lower passivation layer 110b may be applied to have a thickness that is slightly greater than a thickness of the package substrate upper bonding pads 114a and package substrate lower bonding pads 116a, respectively. Alternatively, the package substrate upper passivation layer 110a and package substrate lower passivation layer 110b may be applied so as to have an upper surface that is substantially coplanar with an upper surface of the package substrate upper bonding pads 114a and package substrate lower bonding pads 116a, respectively.

Openings O₁₁₀ₐ may then be formed in the package substrate upper passivation layer 110a so as to expose the upper surface of the package substrate upper bonding pads 114a. Openings O_{110b} may be formed in the package substrate lower passivation layer 110b to expose an upper surface of the package substrate lower bonding pads 116a. The openings O₁₁₀ₐ and the openings O_{110b} may be formed, for example, by using a photolithographic process. In at least one embodiment, the openings O₁₁₀ₐ and the openings O_{110b} may be formed in separate photolithographic processes.

The photolithographic process (e.g., processes) used to form the openings O₁₁₀ₐ may include forming a patterned photoresist mask (not shown) on the package substrate upper passivation layer 110a, and etching (e.g., wet etching, dry etching, etc.) the exposed upper surface of the package substrate upper passivation layer 110a through openings in the photoresist mask. The photoresist mask may be subsequently removed by ashing, dissolving the photoresist mask or by consuming the photoresist mask during the etch process.

The photolithographic process (e.g., processes) used to form the openings O_{110b} may include forming a patterned photoresist mask (not shown) on the package substrate lower passivation layer 110b, and etching (e.g., wet etching, dry etching, etc.) the exposed upper surface of the package substrate lower passivation layer 110b through openings in the photoresist mask. The photoresist mask may be subsequently removed by ashing, dissolving the photoresist mask or by consuming the photoresist mask during the etch process.

After the openings O₁₁₀ₐ are formed in the package substrate upper passivation layer 110a and the openings O_{110b} are formed in the package substrate lower passivation layer 110b, the package substrate upper passivation layer 110a (upper solder resist layer) and the package substrate lower passivation layer 110b (lower solder resist layer) may be cured such as by a thermal cure or ultraviolet (UV) cure.

FIG. 5B illustrates a vertical cross-sectional view of an intermediate structure in which the semiconductor module 120 may be mounted on the package substrate 110, according to one or more embodiments. The semiconductor module 120 may be mounted on the package substrate 110, for example, by a flip chip bonding (FCB) process. The semiconductor die module 121 may be positioned over the package substrate 110, for example, by an electromechanical pick-and-place (PNP) machine. The C4 bumps 121 on the semiconductor die module 121 may then be lowered onto the package substrate upper bonding pads 114a of the package substrate 110 and heated in order to collapse the C4 bumps 121 and bond the C4 bumps 121 to the package substrate upper bonding pads 114a.

FIG. 5C illustrates a vertical cross-sectional view of an intermediate structure in which the package underfill layer 119 may be formed on the package substrate 110 according to one or more embodiments. The package underfill layer 119 may be formed of an epoxy-based polymeric material. As illustrated in FIG. 5C, the package underfill layer 119 may be formed (e.g., injected) under and around the semiconductor module 120 and the C4 bumps 121 to the package substrate 110. The package underfill layer 119 may then be cured, for example, in a box oven for duration in a range from 60 minutes to 120 minutes at a temperature in a range from 120° C. to 180° C. to provide the package underfill layer 119 with a sufficient stiffness and mechanical strength.

FIG. 5D illustrates a vertical cross-sectional view of an intermediate structure in which the TIM layer 170 may be attached to (e.g., formed on) the backside capacitor 210 according to one or more embodiments. A thermally conductive adhesive may or may not be applied to the upper surface of the backside capacitor 210, depending upon the type of TIM layer 170 is being used. A material of the TIM layer 170 may be in the form of a grease, gel, paste, etc. in which case the material may be dispensed onto the thermally conductive adhesive if present or onto the upper surface of the package module. If the TIM layer 170 is a solid, the TIM layer 170 may then be pressed onto the backside capacitor 210 or onto the adhesive if present.

FIG. 5E illustrates a vertical cross-sectional view of an intermediate structure in which the adhesive layer 160 may be applied to the package substrate 110 according to one or more embodiments. The adhesive layer 160 may be dispensed onto the package substrate 110 with a dispensing tool (e.g., automated dispensing tool). The dispensing tool may dispense the adhesive layer 160 in a frame shape around the semiconductor module 120. At the time of application, the adhesive layer 160 may be sufficiently rigid so as to form a semi-solid bead on the surface of the package substrate 110. In at least one embodiment, a viscosity of each the adhesive layer 160 at the time of application may be 50,000 centipoise (cp) or greater. The shape of the semi-solid bead may remain substantially unchanged between the time of application by the dispensing tool and the later time of attaching the package lid 130. The location of the frame shape of the adhesive layer 160 may correspond to a location of the foot portion 130a of the package lid 130. A pressing of the package lid 130 onto the adhesive layer 160 may deform the adhesive layer 160.

FIG. 5F illustrates a vertical cross-sectional view of an intermediate structure in which the package lid 130 may be attached to (e.g., mounted on) the package substrate 110 according to one or more embodiments. In at least one embodiment, the package substrate 110 with the semiconductor module 120 may be placed on a surface. The package lid 130 may then be positioned over the package substrate 110, for example, by an electromechanical pick-and-place (PNP) machine. The package lid 130 may then be lowered down over the semiconductor module 120 and onto the package substrate 110. The foot portion 130a of the package lid 130 may then be aligned with the adhesive layer 160 formed on the package substrate 110. The package lid 130 may then be pressed downward on to the TIM layer 170 by applying a pressing force down onto the package lid 130 so that the foot portion 130a of the package lid 130 may be attached to the package substrate 110 through the adhesive layer 160.

The package lid 130 may then be clamped to the package substrate 110 for a period to allow the adhesive layer 160 to cure and form a secure bond between the package substrate 110 and the package lid 130. The clamping of the package lid 130 to the package substrate 110 may be performed, for example, by using a heat clamp module. The heat clamp module may apply a uniform force across the upper surface of the package lid 130. In one or more embodiments, the heat clamp module may apply the pressing force to the package lid 130.

FIG. 5G illustrates a vertical cross-sectional view of an intermediate structure in which the BGA 180 including a plurality of solder balls 181 may be formed on the package substrate 110 according to one or more embodiments. The plurality of solder balls 181 may be formed on the package substrate lower bonding pads 116a through the openings O_{110b} in the package substrate lower passivation layer 110b. The solder balls 181 may be formed, for example, by an electroplating process. The solder balls 181 may be formed, for example, so as to be located under the foot portion 130a and under the semiconductor module 120 and therebetween. The plurality of solder balls 181 may constitute the BGA 180 that may allow the package structure 100 to be securely mounted (e.g., by surface mount technology (SMT)) on a substrate such as a printed circuit board and electrically coupled to the substrate. Formation of the solder balls 181 may complete the formation of the package structure 100.

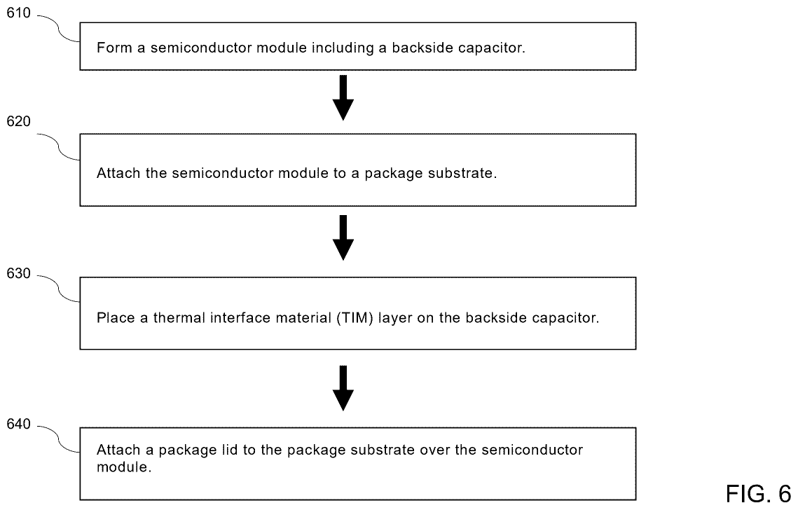

FIG. 6 is a flow chart illustrating a method of forming the package structure 100 according to one or more embodiments. Step 610 includes forming a semiconductor module including a backside capacitor. Step 620 includes attaching the semiconductor module to a package substrate. Step 630 includes placing a thermal interface material (TIM) layer on the backside capacitor. Step 640 includes attaching a package lid to the package substrate over the semiconductor module. The method illustrated in FIG. 6 is not intended to limit the method to a specific sequence of steps.

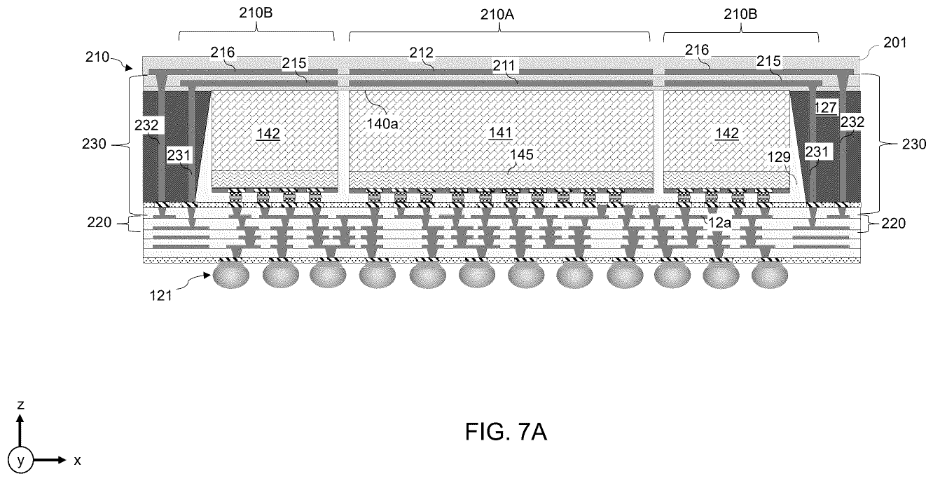

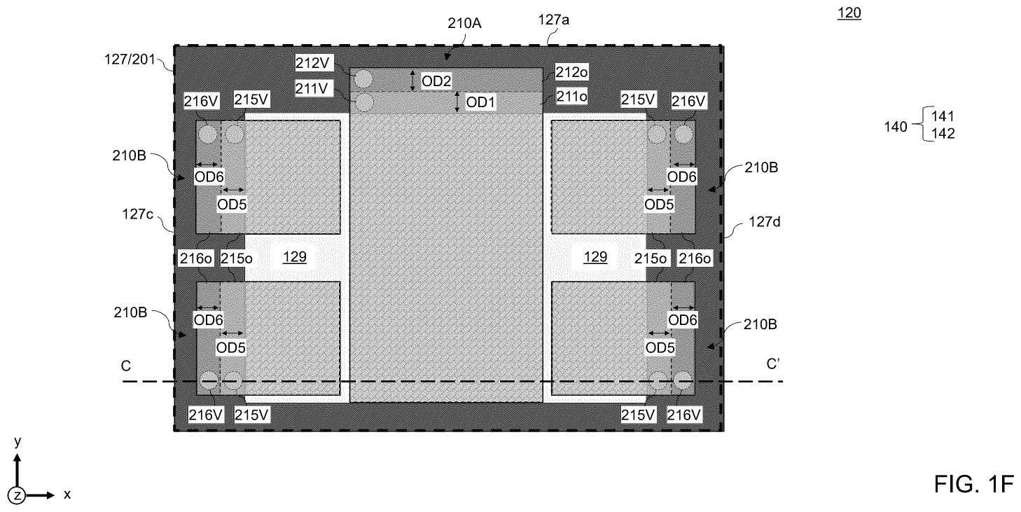

FIGS. 7A-7B are views of the semiconductor module 120 having a first alternative configuration according to one or more embodiments. FIG. 7A is a vertical cross-sectional view of the semiconductor module 120 having the first alternative configuration according to one or more embodiments. As illustrated in FIG. 7A, the semiconductor module 120 having the first alternative configuration may be substantially similar to the semiconductor module 120 in FIGS. 1A-1F. However, in the first alternative configuration, semiconductor module 120 may include second semiconductor dies 142 (e.g., HBM dies) on opposing sides of the first semiconductor die 141. The backside capacitor 210 may also include second capacitors 210B on opposing sides (e.g., in the x-direction) of the semiconductor module 120. The semiconductor module 120 may also include connecting structures 230 and distribution structures 220 on opposing sides (e.g., in the x-direction) of the semiconductor module 120. With this configuration, a total capacitance of the backside capacitor 210 may be greater than the capacitance in the backside capacitor 210 of FIG. 1A-1F.

FIG. 7B is a top-down view of the semiconductor module 120 having the first alternative configuration according to one or more embodiments. The vertical cross-sectional view in FIG. 7A is along the line C-C′ in FIG. 7B. As illustrated in FIG. 7B, the semiconductor module 120 having the first alternative configuration may have a total of five capacitors including one first capacitor 210A over the first semiconductor die 141 and four second capacitors over the second semiconductor dies 142. As further illustrated in FIG. 7B, the second capacitors 210B on opposing sides of the first semiconductor die 141 may be configured as mirror images of each other. Further, each of the five capacitors may have a dedicated connecting structure 230 and distribution structure 220 in the semiconductor module 120 having the first alternative configuration.

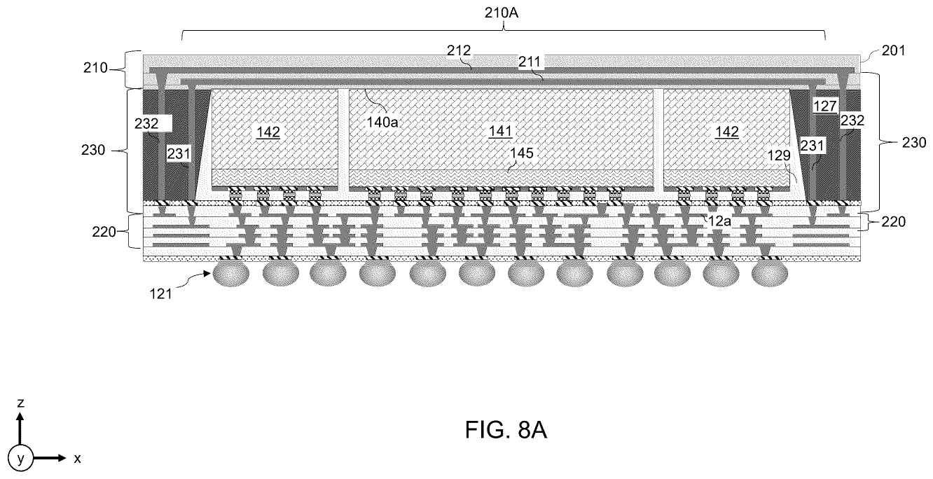

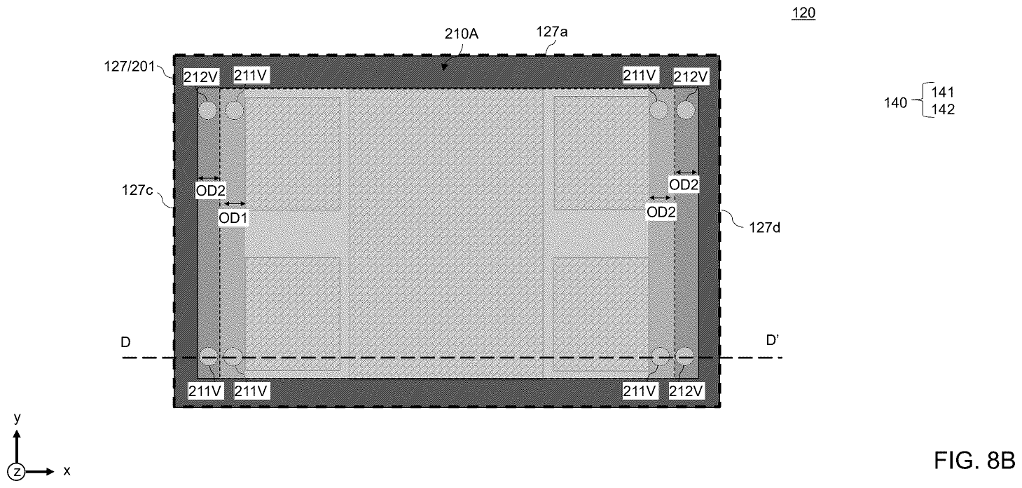

FIGS. 8A-8B are views of the semiconductor module 120 having a second alternative configuration according to one or more embodiments. FIG. 8A is a vertical cross-sectional view of the semiconductor module 120 having the second alternative configuration according to one or more embodiments. As illustrated in FIG. 8A, the semiconductor module 120 having the second alternative configuration may be substantially similar to the semiconductor module 120 having the first alternative configuration in FIGS. 7A-7B.

However, in the second alternative configuration, the second capacitor 210B may be omitted from the backside capacitor 210. The backside capacitor 210 in the second alternative configuration may include a first capacitor 210A that covers substantially all of the semiconductor module 120. Similar to the first alternative configuration in FIGS. 7A and 7B, the semiconductor module 120 having the second alternative configuration may also have connecting structures 230 and distribution structures 220 on opposing sides (e.g., in the x-direction) of the semiconductor module 120. With this configuration, a total capacitance of the backside capacitor 210 may be greater than the capacitance in the backside capacitor 210 of FIG. 1A-1F and the backside capacitor 210 of the first alternative configuration in FIGS. 7A-7B.

FIG. 8B is a top-down view of the semiconductor module 120 having the second alternative configuration according to one or more embodiments. The vertical cross-sectional view in FIG. 8A is along the line D-D′ in FIG. 8B. As illustrated in FIG. 8B, the semiconductor module 120 having the second alternative configuration may have four sets of the first upper via 211V and the second upper via 212V located at the four corners of the first capacitor 210A. Further, each set of the first upper via 211V and the second upper via 212V have a dedicated connecting structure 230 and distribution structure 220 in the semiconductor module 120 having the second alternative configuration.

It should be noted that semiconductor module 120 having the second alternative configuration does not necessarily include four sets of the first upper via 211V and the second upper via 212V, but may include more or fewer sets of the first upper via 211V and the second upper via 212V. In at least one embodiment, the semiconductor module 120 having the second alternative configuration may include one or more sets of the first upper via 211V and the second upper via 212V. In addition, the sizes and locations of the sets of the first upper via 211V and the second upper via 212V may be different than the sizes and locations shown in FIG. 8B.

Referring to FIGS. 1A-8B, a semiconductor module 120 may include an interposer 10, a plurality of semiconductor dies 140 on the interposer 10, wherein each semiconductor die of the plurality of semiconductor dies 140 has a frontside surface facing the interposer 10 and a backside surface 140a opposite to the interposer 10, and a backside capacitor 210 on the backside surface 140a of at least one of the plurality of semiconductor dies 140 and electrically coupled to the interposer 10.

In one embodiment, the semiconductor module 120 may further include an upper molding layer 127 around the plurality of semiconductor dies 140, wherein the backside capacitor 210 may be on the upper molding layer 127. In one embodiment, the backside capacitor 210 may include a passivation film 201 on the upper surface of the upper molding layer 127, and a pair of parallel metal films 211/212, 215/216 in the passivation film 201 and separated by the passivation film 201. In one embodiment, the passivation film 201 may include a plurality of passivation layers 201L1, 201L2, 201L3 including a first passivation layer 201L1 on the surface of the upper molding layer 127, wherein a first metal film 211, 215 of the pair of parallel metal films 211/212, 215/216 may be on the first passivation layer 201L1, a second passivation layer 201L2 on the first passivation layer 201L1, wherein a second metal film 212, 216 of the pair of parallel metal films 211/212, 215/216 may be on the second passivation layer 201L2, and a third passivation layer 201L3 on the second passivation layer 201L2 and the second metal film 212, 216. In one embodiment, the second passivation layer 201L2 may separate the first metal film 211, 215 from the second metal film 212, 216 and may include a charge separating layer that may contain an electric field in the backside capacitor 210. In one embodiment, the semiconductor module 120 may further include a connecting structure 230 configured to electrically couple the pair of parallel metal films 211/212, 215/216 to the interposer 10. In one embodiment, the interposer 10 may include a distribution structure 220 including a plurality of distribution lines 221, 222, and the connecting structure 230 may be configured to electrically couple the pair of parallel metal films 211/212, 215/216 to the plurality of distribution lines 221, 222. In one embodiment, the connecting structure 230 may include a pair of lower connecting portions 221V/13a1, 222V/13a2 in the interposer 10 and connected to the plurality of distribution lines 221, 222 of the distribution structure 220, a pair of through molding vias (TMVs) 231, 232 in the upper molding layer 127 and connected to the pair of lower connecting portions 221V/13a1, 222V/13a2, and a pair of upper vias 211V/212V, 215V/216V in the passivation film 201 and connected to the pair of TMVs 231, 232 and the pair of parallel metal films 211/212, 215/216. In one embodiment, the pair of TMVs 231, 232 may be located in the upper molding layer 127 outside the plurality of semiconductor dies 140. In one embodiment, the pair of parallel metal films 211/212, 215/216 may be located over a semiconductor die 140 of the plurality of semiconductor dies 140. Each metal film of the pair of parallel metal films 211/212, 215/216 may include an overhang portion OD1/OD2, OD5/OD6 which extends beyond a side of the semiconductor die 140 of the plurality of semiconductor dies 140, and an upper via of the pair of upper vias 211V/212V, 215V/216V may be connected to the overhang portion OD1/OD2, OD5/OD6. An area of the backside capacitor 210 may be in a range from 10% to 100% of an area of the semiconductor module 120. A thickness of the backside capacitor 210 may be in a range from 0.1 μm to 10,000 μm.

Referring again to FIGS. 1A-8B, a method of making a semiconductor module 120 may include forming an interposer 10, attaching a plurality of semiconductor dies 140 to the interposer 10, wherein each semiconductor die of the plurality of semiconductor dies 140 has a frontside surface facing the interposer 10 and a backside surface 140a opposite to the interposer 10, forming an upper molding layer 127 around the plurality of semiconductor dies 140, and forming a backside capacitor 210 on the backside surface 140a of at least one of the plurality of semiconductor dies 140 and upper molding layer 127, such that the backside capacitor 210 may be electrically coupled to the interposer 10 through the upper molding layer 127.

In one embodiment, the forming of the backside capacitor 210 may include forming a passivation film 201 on the upper surface of the upper molding layer 127, and forming a pair of parallel metal films 211/212, 215/216 in the passivation film 201 and separated by the passivation film 201. In one embodiment, the forming of the passivation film 201 may include forming a first passivation layer 201L1 on the surface of the upper molding layer 127, wherein the forming of the pair of parallel metal films 211/212, 215/216 may include forming a first metal film 211, 215 of the pair of parallel metal films 211/212, 215/216 on the first passivation layer 201L1, forming a second passivation layer 201L2 on the first passivation layer 201L1, wherein the forming of the pair of parallel metal films 211/212, 215/216 may include forming a second metal film 212, 216 of the pair of parallel metal films 211/212, 215/216 on the second passivation layer 201L2, and forming a third passivation layer 201L3 on the second passivation layer 201L2 and the second metal film 212, 216. In one embodiment, the method may further include forming a connecting structure 230 configured to electrically couple the pair of parallel metal films 211/212, 215/216 to the interposer 10. In one embodiment, the forming of the interposer 10 may include forming a distribution structure 220 including a plurality of distribution lines 221, 222, and the forming of the connecting structure 230 may include forming the connecting structure 230 to electrically couple the pair of parallel metal films 211/212, 215/216 to the plurality of distribution lines 221, 222 of the distribution structure 220. In one embodiment, the forming of the connecting structure 230 may include forming a pair of lower connecting portions 221V/13a1, 222V/13a2 in the interposer 10 and connected to the plurality of distribution lines 221, 222, forming a pair of through molding vias (TMVs) 231, 232 in the upper molding layer 127 and connected to the pair of lower connecting portions 221V/13a1, 222V/13a2, and forming a pair of upper vias 211V/212V, 215V/216V in the passivation film 201 and connected to the pair of TMVs 231, 232 and the pair of parallel metal films 211/212, 215/216.

Referring again to FIGS. 1A-8B, a package structure 100 may include a package substrate 110, a semiconductor module 120 on the package substrate 110, including an interposer 10, a plurality of semiconductor dies 140 on the interposer 10, and a backside capacitor 210 on the plurality of semiconductor dies 140 and electrically coupled to the interposer 10, wherein the backside capacitor 210 may include a passivation film 201 and a pair of parallel metal films 211/212, 215/216 in the passivation film 201, a thermal interface material 170 on the backside capacitor 210 and contacting the passivation film 201, wherein the pair of parallel metal films 211/212, 215/216 may be between the plurality of semiconductor dies 140 and the thermal interface material 170, and a package lid on the thermal interface material 170 and attached to the package substrate 110.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor module, comprising:
an interposer;
a plurality of semiconductor dies on the interposer, wherein each semiconductor die of the plurality of semiconductor dies has a frontside surface facing the interposer and a backside surface opposite to the interposer; and
a backside capacitor on the backside surface of at least one of the plurality of semiconductor dies and electrically coupled to the interposer.

2. The semiconductor module of claim 1, further comprising:
an upper molding layer around the plurality of semiconductor dies, wherein the backside capacitor is on the upper molding layer.

3. The semiconductor module of claim 2, wherein the backside capacitor comprises:
a passivation film on an upper surface of the upper molding layer; and
a pair of parallel metal films in the passivation film and separated by the passivation film.

4. The semiconductor module of claim 3, wherein the passivation film comprises a plurality of passivation layers comprising:
a first passivation layer on the surface of the upper molding layer, wherein a first metal film of the pair of parallel metal films is on the first passivation layer;
a second passivation layer on the first passivation layer, wherein a second metal film of the pair of parallel metal films is on the second passivation layer; and
a third passivation layer on the second passivation layer and the second metal film.

5. The semiconductor module of claim 4, wherein the second passivation layer separates the first metal film from the second metal film and comprises a charge separating layer containing an electric field in the backside capacitor.

6. The semiconductor module of claim 3, further comprising:
a connecting structure configured to electrically couple the pair of parallel metal films to the interposer.

7. The semiconductor module of claim 6, wherein the interposer comprises a distribution structure including a plurality of distribution lines, and the connecting structure is configured to electrically couple the pair of parallel metal films to the plurality of distribution lines.

8. The semiconductor module of claim 7, wherein the connecting structure comprises:
a pair of lower connecting portions in the interposer and connected to the plurality of distribution lines of the distribution structure;
a pair of through molding vias (TMVs) in the upper molding layer and connected to the pair of lower connecting portions; and
a pair of upper vias in the passivation film and connected to the pair of TMVs and the pair of parallel metal films.

9. The semiconductor module of claim 8, wherein the pair of TMVs are located in the upper molding layer outside the plurality of semiconductor dies.

10. The semiconductor module of claim 9, wherein the pair of parallel metal films is located over a semiconductor die of the plurality of semiconductor dies.

11. The semiconductor module of claim 10, wherein each metal film of the pair of parallel metal films comprises an overhang portion which extends beyond a side of the semiconductor die of the plurality of semiconductor dies, and an upper via of the pair of upper vias is connected to the overhang portion.

12. The semiconductor module of claim 2, wherein an area of the backside capacitor is in a range from 10% to 100% of an area of the semiconductor module.

13. The semiconductor module of claim 1, wherein a thickness of the backside capacitor is in a range from 0.1 μm to 10,000 μm.

14. A method of making a semiconductor module, the method comprising:
forming an interposer;
attaching a plurality of semiconductor dies to the interposer, wherein each semiconductor die of the plurality of semiconductor dies has a frontside surface facing the interposer and a backside surface opposite to the interposer;
forming an upper molding layer around the plurality of semiconductor dies; and
forming a backside capacitor on the backside surface of at least one of the plurality of semiconductor dies and the upper molding layer, such that the backside capacitor is electrically coupled to the interposer through the upper molding layer.

15. The method of claim 14, wherein the forming of the backside capacitor comprises:
forming a passivation film on an upper surface of the upper molding layer; and
forming a pair of parallel metal films in the passivation film and separated by the passivation film.

16. The method of claim 15, wherein the forming of the passivation film comprises:
forming a first passivation layer on the surface of the upper molding layer, wherein the forming of the pair of parallel metal films comprises forming a first metal film of the pair of parallel metal films on the first passivation layer;
forming a second passivation layer on the first passivation layer, wherein the forming of the pair of parallel metal films comprises forming a second metal film of the pair of parallel metal films on the second passivation layer; and
forming a third passivation layer on the second passivation layer and the second metal film.

17. The method of claim 15, further comprising:
forming a connecting structure configured to electrically couple the pair of parallel metal films to the interposer.

18. The method of claim 17, wherein the forming of the interposer comprises forming a distribution structure including a plurality of distribution lines, and the forming of the connecting structure comprises forming the connecting structure to electrically couple the pair of parallel metal films to the plurality of distribution lines of the distribution structure.

19. The method of claim 18, wherein the forming of the connecting structure comprises:
forming a pair of lower connecting portions in the interposer and connected to the plurality of distribution lines;
forming a pair of through molding vias (TMVs) in the upper molding layer and connected to the pair of lower connecting portions; and
forming a pair of upper vias in the passivation film and connected to the pair of TMVs and the pair of parallel metal films.

20. A package structure, comprising:
a package substrate;
a semiconductor module on the package substrate, comprising:
an interposer;
a plurality of semiconductor dies on the interposer; and
a backside capacitor on the plurality of semiconductor dies and electrically coupled to the interposer, wherein the backside capacitor comprises a passivation film and a pair of parallel metal films in the passivation film;
a thermal interface material on the backside capacitor and contacting the passivation film, wherein the pair of parallel metal films are between the plurality of semiconductor dies and the thermal interface material; and
a package lid on the thermal interface material and attached to the package substrate.
